(19) United States
(12) Patent Application Publication
(10) Pub. No.: US 2026/0013186 A1
(43) Pub. Date: Jan. 8, 2026

(54) ANNEALING PROCESSES IN GATE-ALL-AROUND (GAA) DEVICES

(71) Applicant: Taiwan Semiconductor Manufacturing Company, Ltd., Hsin-Chu (TW)

(72) Inventors: Pei-Fang Hsieh, Hsinchu (TW); Yi-Chao Wang, Hsinchu City (TW); Liang-Yin Chen, Hsinchu City (TW); Po-Kang Ho, Taoyuan City (TW); Chu-Yen Hsiao, Taoyuan City (TW); Tsai-Yu Huang, Hsinchu (TW); Chien-Hao Chen, Hsinchu (TW)

(21) Appl. No.: 18/927,082

(22) Filed: Oct. 25, 2024

Related U.S. Application Data
(60) Provisional application No. 63/666,784, filed on Jul. 2, 2024.

(51) Int. Cl. H01L 29/06; H01L 21/225; H01L 21/265; H01L 27/092; H01L 29/417; H01L 29/423; H01L 29/66; H01L 29/775; H01L 29/786

(52) U.S. Cl. CPC H10D 62/125; H01L 21/225; H10D 30/014; H10D 62/116; H10D 64/258; H01L 21/265; H10D 30/43; H10D 30/6735; H10D 30/6757; H10D 62/121; H10D 84/856

(57) ABSTRACT

A stack of first semiconductor layers and second semiconductor layers is formed. The first semiconductor layers each have a first material composition. The second semiconductor layers each have a second material composition different from the first material composition. The first semiconductor layers interleave with the second semiconductor layers in the stack. The second semiconductor layers are replaced with a plurality of dielectric layers. Source/drain features are formed on opposite sides of the first semiconductor layers, such that junctions are formed between the source/drain features and the first semiconductor layers. One or more annealing processes are performed. At least one of the one or more annealing processes facilitates a push of the junction toward the first semiconductor layers.

### PRIORITY DATA

The present application is a utility application of provisional U.S. Patent Application No. 63/666,784, filed on Jul. 2, 2024, entitled “Annealing processes in gate-all-around (GAA) devices”, the disclosure of which is herein incorporated by reference in its entirety.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Recently, multigate devices have been introduced to improve gate control. Multigate devices have been observed to increase gate-channel coupling, reduce OFF-state current, and/or reduce short-channel effects (SCEs). One such multigate device is the gate-all around (GAA) device, which includes a gate structure that can extend, partially or fully, around a channel region to provide access to the channel region on at least two sides. GAA devices enable aggressive scaling down of IC technologies, maintaining gate control and mitigating SCEs, while seamlessly integrating with conventional IC manufacturing processes. As GAA devices continue to scale, challenges have arisen. For example, it may be more difficult to maintain a uniform junction profile between the channel and source/drain regions. Furthermore, undesirable electrical shorting between a source/drain feature and a metal-containing gate structure may occur. As a result, device performance and/or production yield may be unsatisfactory. Therefore, although existing IC structures and fabrication techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flowchart of a method for fabricating a semiconductor structure according to various aspects of the present disclosure.

FIG. 2 is a top view of a semiconductor structure according to some embodiments of the present disclosure.

FIGS. 3, 4A, 5A, 6A, 7A, 8A, 9A, 10, 11A, and 12A are cross-sectional side views of a semiconductor structure along the line A-A′ in FIG. 2, at various fabrication stages, according to some embodiments of the present disclosure.

FIGS. 4B, 5B, 6B, 7B, 8B, 9B, 11B, and 12B are enlarged views of a portion of the semiconductor structure in FIGS. 4A-9A and 11A-12A, respectively, according to some embodiments of the present disclosure.

FIG. 11C is a cross-sectional side view of the semiconductor structure in FIG. 11A and along the line B-B′ as in FIG. 2, according to some embodiments of the present disclosure.

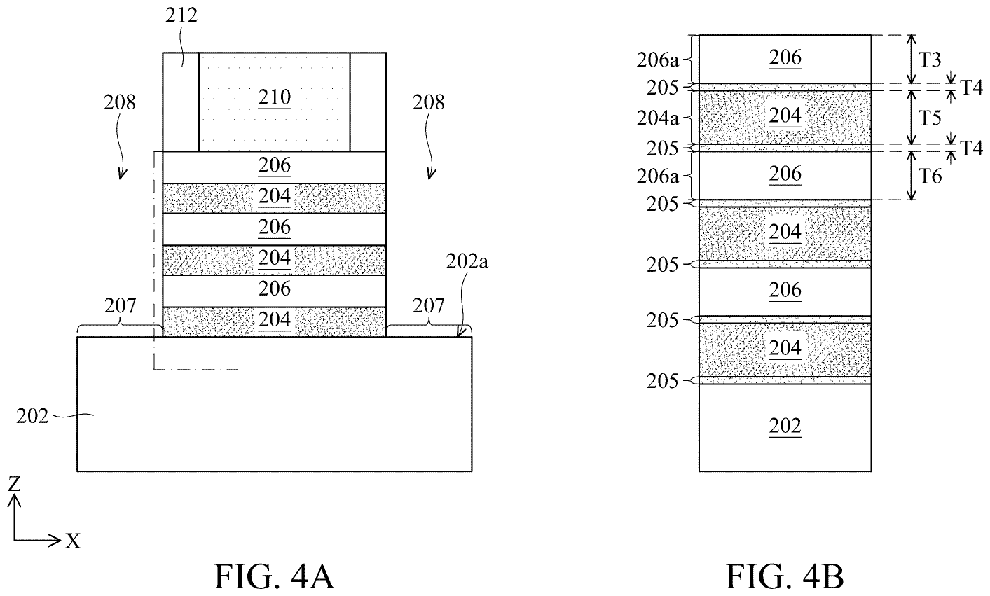

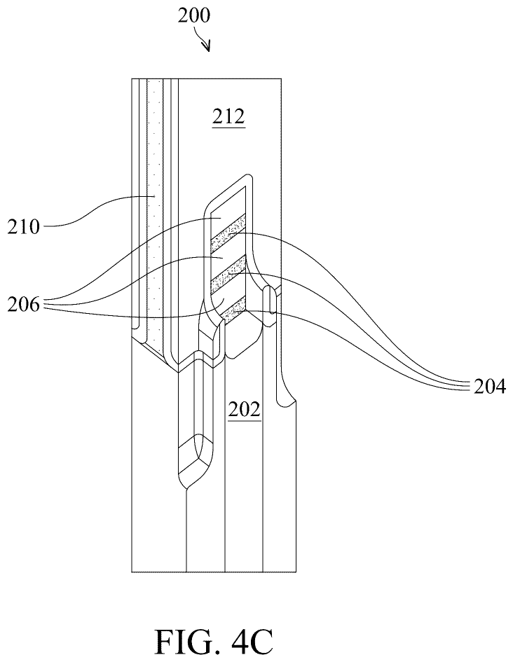

FIGS. 4C, 5C, 6C, 7C, 8C, and 16-19 are three-dimensional perspective views of a semiconductor structure at various stages of fabrication, according to some embodiments of the present disclosure.

FIGS. 13-15 and 20-22 are cross-sectional side views of a semiconductor structure at various stages of fabrication, according to some embodiments of the present disclosure.

FIG. 23 is a circuit diagram of a memory cell according to some embodiments of the present disclosure.

FIG. 24 is a block diagram of a semiconductor fabrication facility according to some embodiments of the present disclosure.

### DETAILED DESCRIPTION

The following disclosure provides many different embodiments, or examples, for implementing different features. Reference numerals and/or letters may be repeated in the various examples described herein. This repetition is for the purpose of simplicity and clarity and does not in itself dictate a relationship between the various disclosed embodiments and/or configurations. Further, specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Moreover, the formation of a feature on, connected to, and/or coupled to another feature in the present disclosure may include embodiments in which the features are formed in direct contact, and may also include embodiments in which additional features may be formed interposing the features, such that the features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

Multi-gate devices (e.g. gate-all-around (GAA) devices) have been introduced in an effort to improve gate control by increasing gate-channel coupling, reduce OFF-state current, and reduce short-channel effects (SCEs). GAA devices can be aggressively scaled down while maintaining gate control and mitigating SCEs. However, GAA devices may still face certain challenges. For example, dipole layers can be formed on a gate dielectric layer, where dipole dopants are driven into the gate dielectric to tune a threshold voltage of a GAA device. However, as GAA devices continue to get scaled down, it may become more difficult to maintain a uniform junction profile between the source/drain and the channel. Furthermore, undesirable electrical shorting between the source/drain and the metal-containing gate structure may occur. These issues may lead to lower yields and/or degraded device performance. The present disclosure pertains to a semiconductor structure fabrication process flow that addresses the issues discussed above.

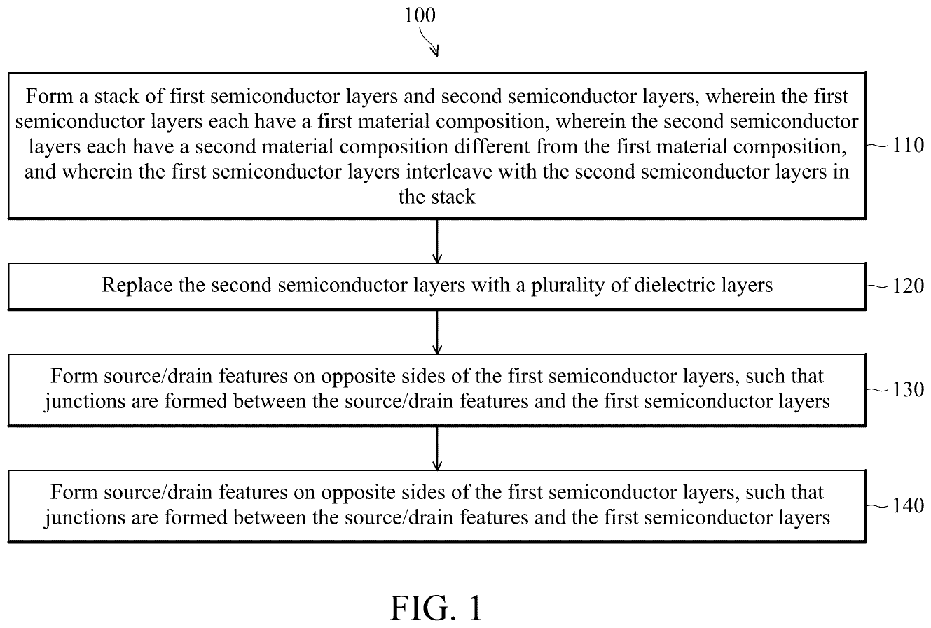

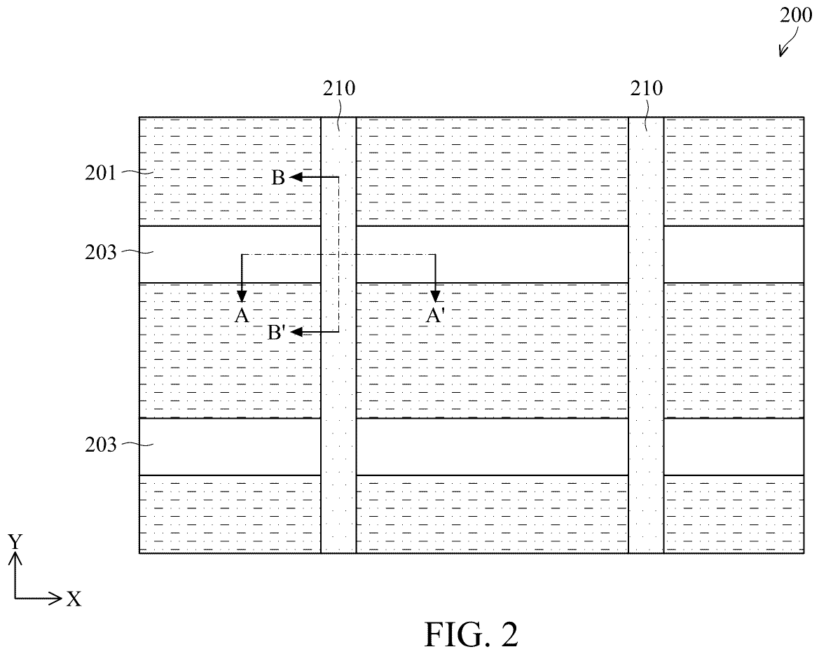

Referring now to FIG. 1, a flow chart of an example method 100 for fabricating an embodiment of a semiconductor device is illustrated. In some embodiments, the semiconductor device is a GAA device where its gate structure, or portions thereof, are formed around all-sides of a channel region (e.g. surrounding a portion of a channel region). In some instances, a GAA device may also be referred to as a quad-gate device where the channel region has four sides and the gate structure is formed on all four sides. The channel region of a GAA device may include one or more semiconductor layers, each of which may be in one of many different shapes, such as wire (or nanowire), sheet (or nanosheet), bar (or nano-bar), and/or other suitable shapes. In embodiments, the channel region of a GAA device may have multiple horizontal semiconductor layers (such as nanowires, nanosheets, or nano-bars) (hereinafter collectively referred to as “nanochannels”) vertically spaced, making the GAA device a stacked horizontal GAA device. The GAA devices presented herein may be a complementary metal-oxide-semiconductor (CMOS) GAA device, a p-type metal-oxide-semiconductor (pMOS) GAA device, or an n-type metal-oxide-semiconductor (nMOS) GAA device. Further, the GAA devices may have one or more channel regions associated with a single, contiguous gate structure, or multiple gate structures. One of ordinary skill may recognize other examples of semiconductor devices that may benefit from aspects of the present disclosure. For example, other types of metal-oxide semiconductor field effect transistors (MOSFETs), such as planar MOSFETs, FinFETs, other multi-gate FETs may benefit from the present disclosure. The GAA devices and methods of manufacture that are proposed in the present disclosure exhibit desirable properties, examples being: reduced doping diffusion, reduced built-in stress, reduced device degradation, improved silicon performance, higher current drive, reduced short-channel effects (SCEs), and decreased capacitance between adjacent conductive regions, such as between a source/drain region and adjacent SiGe residue.

The method 100 includes a step 110 to form a stack of first semiconductor layers and second semiconductor layers. The first semiconductor layers each have a first material composition. The second semiconductor layers each have a second material composition different from the first material composition. The first semiconductor layers interleave with the second semiconductor layers in the stack.

The method 100 includes a step 120 to replace the second semiconductor layers with a plurality of dielectric layers.

The method 100 includes a step 130 to form source/drain features on opposite sides of the first semiconductor layers, such that junctions are formed between the source/drain features and the first semiconductor layers.

The method 100 includes a step 140 to perform one or more annealing processes. At least one of the one or more annealing processes facilitates a push of the junction toward the first semiconductor layers.

In some embodiments, the forming of the source/drain features comprises an epitaxial growth process followed by an ion implantation process. At least one of the one or more annealing processes is performed after the epitaxial growth process but before the ion implantation process.

In some embodiments, the forming of the source/drain features comprises an epitaxial growth process followed by an ion implantation process. At least one of the one or more annealing processes is performed after the ion implantation process.

In some embodiments, at least some of the junctions lack a concave profile or a convex profile in a cross-sectional side view.

In some embodiments, at least one of the annealing processes is performed at a temperature greater than about 1050 degrees Celsius.

In some embodiments, at least one of the annealing processes is performed with a dwell time of less than about 1 second.

In some embodiments, at least one of the annealing processes is performed at a pressure in a range between about 1 torr and about 760 torrs.

In some embodiments, the one or more annealing processes includes a first annealing process and a second annealing process. In some embodiments, the first annealing process and the second annealing process use different types of annealing techniques. In some embodiments, the second annealing process has a shorter dwell time than the first annealing process. In some embodiments, the dwell time for the second annealing process is in a range between about 1 nanosecond and about 0.1 millisecond. In some embodiments, the second annealing process, but not the first annealing process, includes a laser annealing process.

It is understood that the method 100 may include steps that are performed before, during, and/or after the steps 110-150. For example, the method 100 may include a step of removing the dielectric layers, and a step of forming metal-containing gate structures in place of the removed dielectric layers. In some embodiments, at least one of the one or more annealing processes is performed after the dielectric layers are removed but before the metal-containing gate structures are formed. For reasons of simplicity, these steps are not specifically discussed in detail herein.

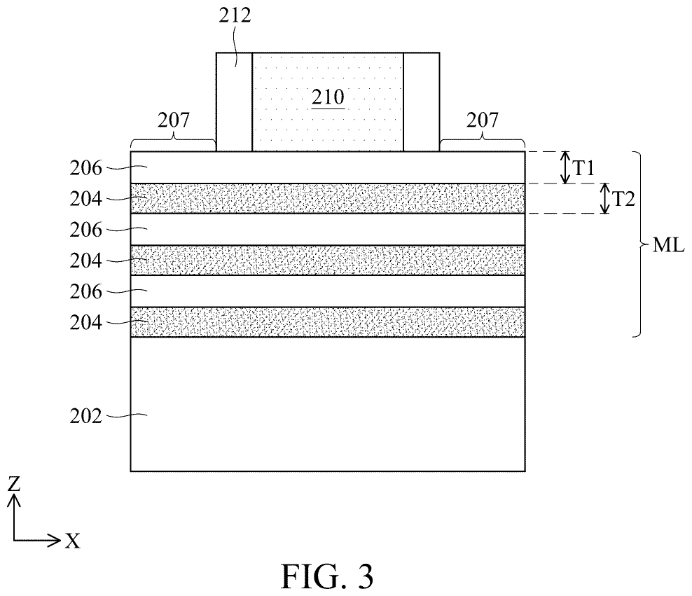

Referring to FIGS. 2 and 3, a semiconductor structure 200 fabricated according to the various aspects of the present disclosure includes semiconductor substrate 202 and a plurality of fins 203 protruding from the semiconductor substrate 202. The fins 203 and separated by isolation features 201 and one or more dummy gate stacks 210 disposed over the fins 203.

In some embodiments, the semiconductor substrate 202 includes a semiconductor material, such as bulk silicon (Si). Alternatively, or additionally, another elementary semiconductor, such as germanium (Ge) in a crystalline structure, may also be included in the semiconductor substrate 202. The semiconductor substrate 202 may also include a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb), or combinations thereof. The semiconductor substrate 202 may also include a semiconductor-on-insulator substrate, such as Si-on-insulator (SOI), SiGe-on-insulator (SGOI), Ge-on-insulator (GOI) substrates.

Portions of the semiconductor substrate 202 may be doped and referred to as doped portions. The doped portions may be doped with p-type dopants, such as boron (B) or boron fluoride (BF3), or doped with n-type dopants, such as phosphorus (P) or arsenic (As). The doped portions may also be doped with combinations of p-type and n-type dopants (e.g. to form a p-type well and an adjacent n-type well). The doped portions may be formed directly on the semiconductor substrate 202, in a p-well structure, in an n-well structure, in a dual-well structure, or using a raised structure.

In some embodiments, semiconductor layers 204 and 206 (collectively referred to as a “multi-layer stack” or “ML”) are formed over the semiconductor substrate 202 in an interleaving or alternating fashion, extending vertically (e.g. along the Z-direction in FIG. 3) from the semiconductor substrate 202. For example, a semiconductor layer 204 is disposed over the semiconductor substrate 202, a semiconductor layer 206 is disposed over the semiconductor layer 204, another semiconductor layer 204 is disposed over the semiconductor layer 206, so on and so forth. In the depicted embodiments, there are three layers of semiconductor layers 206 and three layers of semiconductor layers 204 alternating between each other. However, there may be any appropriate number of layers in the ML. For example, there may be 2 to 10 layers of semiconductor layers 206, alternating with 2 to 10 layers of semiconductor layers 204 in the ML. The material compositions of the semiconductor layers 206 and the semiconductor layers 204 are configured such that they have an etching selectivity in a subsequent etching process. For example, in some embodiments, the semiconductor layers 204 contain silicon germanium (SiGe), while the semiconductor layers 206 contain silicon (Si). In some other embodiments, the semiconductor layers 206 contain SiGe, while the semiconductor layers 204 contain Si. In the depicted embodiment, each of the semiconductor layers 206 has a substantially same thickness (e.g., less than 5% difference between two semiconductor layers 206), depicted in FIG. 3 as thickness T1, while each of the semiconductor layers 204 has a substantially same thickness (e.g., less than 5% difference between two semiconductor layers 204), depicted in FIG. 3 as thickness T2. T1 and T2 are about 2 nanometers (nm) to about 12 nm.

The stack of semiconductor layers 204 and 206 are then patterned into a plurality of fin structures, for example, into the fins 203 as in FIG. 2. Each of the fins 203 includes a stack of the semiconductor layers 204 and 206 disposed in an alternating manner with respect to one another. The fins 203 each extends lengthwise (e.g. longitudinally) in a horizontal direction (e.g. in the Y-direction) and are separated from each other (e.g. laterally) in a different horizontal direction (e.g. in the X-direction), as shown in FIG. 2. It is understood that the X-direction and the Y-direction are perpendicular to each other, and that the Z-direction is a vertical direction that is orthogonal (or normal) to a plane defined by the X-direction and the Y-direction. The semiconductor substrate 202 may have its top surface aligned in parallel to the X-Y plane.

The fins 203 may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins. The patterning may utilize multiple etching processes which may include a dry etching and/or wet etching. The regions in which the fins are formed will be used to form active devices through subsequent processing and are thus referred to as active regions. For example, each of the fins 203 is formed in an active region. Both of the fins 203 in FIG. 2 protrude out of the semiconductor substrate 202 (e.g., the doped portions).

The semiconductor structure 200 includes isolation features 201, which may include shallow trench isolation (STI) features in some embodiments. The isolation features 201 are formed on the semiconductor substrate 202 and surround the active regions. In some examples, formation of the isolation features 201 includes etching trenches into the semiconductor substrate 202 between the active regions and filling the trenches with one or more dielectric materials such as silicon oxide, silicon nitride, silicon oxynitride, other suitable materials, or combinations thereof. Any appropriate methods, such as a chemical vapor deposition (CVD) process, an atomic layer deposition (ALD) process, a physical vapor deposition (PVD) process, a plasma-enhanced CVD (PECVD) process, a plasma-enhanced ALD (PEALD) process, and/or combinations thereof may be used for depositing the isolation features 201. The isolation features 201 may have a multi-layer structure such as a thermal oxide liner layer over the semiconductor substrate 202 and a filling layer (e.g., silicon nitride or silicon oxide) over the thermal oxide liner layer. Alternatively, the isolation features 201 may be formed using any other isolation formation techniques. Although not depicted, in some embodiments, the fins 203 are located above a top surface of the isolation features 201 (e.g. protrude out of the isolation features 201) and are also located above a top surface of the semiconductor substrate 202.

Referring to FIGS. 2 and 3, the dummy gate stacks 210 are formed over a portion of each of the fins 203, and over the isolation features 201, in between the fins 203. The dummy gate stacks 210 may be configured to extend lengthwise (e.g. longitudinally) in parallel to each other, for example, each along the X-direction, as shown in FIG. 2. In some embodiments, each dummy gate stack 210 wraps around the top surface and side surfaces of each of the fins 203. The dummy gate stack 210 may include polysilicon. In some embodiments, the dummy gate stack 210 also includes one or more mask layers, which are used to pattern the dummy gate electrode layers. The dummy gate stack 210 may undergo a gate replacement process through subsequent processing to form metal gates, such as a high-k metal gate, as discussed in greater detail below. The dummy gate stack 210 may also undergo a second gate replacement process to form a dielectric based gate that electrically isolates the semiconductor structure 200 from neighboring devices. The dummy gate stack 210 may be formed by a procedure including deposition, lithography patterning, and etching processes. The deposition processes may include CVD, ALD, PVD, other suitable methods, and/or combinations thereof.

Referring to FIG. 3, gate spacers 212 are formed on sidewalls of the dummy gate stack 210. The gate spacers 212 include one or more dielectric materials and may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, or combinations thereof. The gate spacers 212 may include a single layer or a multi-layer structure. In some embodiments, each of the gate spacers 212 may have a thickness (e.g. measured in the Y-direction) in a range from about 3 nm to about 10 nm. A thickness within the stated range of values may be needed for device performance, especially for advanced technology nodes. In some embodiments, the gate spacers 212 may be formed by depositing a spacer layer (containing the dielectric material) over the dummy gate stack 210, followed by an anisotropic etching process to remove portions of the spacer layer from the top surfaces of the dummy gate stack 210. After the etching process, portions of the spacer layer on the sidewall surfaces of the dummy gate stack 210 substantially remain and become the gate spacers 212. In some embodiments, the anisotropic etching process is a dry (e.g. plasma) etching process. Additionally, or alternatively, the formation of the gate spacers 212 may also involve chemical oxidation, thermal oxidation, ALD, CVD, and/or other suitable methods. In the active regions, the gate spacers 212 are formed over the top layer of the semiconductor layers 204 and 206. Accordingly, the gate spacers 212 may also be interchangeably referred to as top spacers 212. In some examples, one or more material layers (not shown) may also be formed between the dummy gate stack 210 and the corresponding gate spacers 212. The one or more material layers may include an interfacial layer and/or a high-k dielectric layer (e.g., having a dielectric constant greater than a dielectric constant of silicon oxide, which is about 3.9), as examples.

Referring now to FIGS. 4A-4C, various views of the semiconductor structure 200 are illustrated. In more detail, FIG. 4A is an X-cut cross-sectional side view of the semiconductor structure 200 taken along the cutline A-A′ of FIG. 2, FIG. 4B is an enlarged view of a portion (in the dotted rectangle) of the semiconductor structure 200 of FIG. 4A, and FIG. 4C is a three-dimensional perspective view of the semiconductor structure 200. For reasons of consistency, similar components appearing in FIGS. 4A-4C will be labeled the same unless otherwise noted.

The exposed portions of the fins 203 (i.e., source/drain regions 207 of the fins 203 that are not covered by the dummy gate stack 210) are at least partially removed to form source/drain recesses (trenches) 208. Source/drain region(s) may refer to a source or a drain, individually or collectively, depending upon the context. In the depicted embodiment, an etching process completely removes the ML in the source/drain regions 207 of the fins 203, thereby exposing substrate portions of the fins 203 in the source/drain regions 207. The source/drain recesses 208 thus have sidewalls defined by remaining portions of the ML, which are disposed under the dummy gate stack 210, and bottoms defined by the semiconductor substrate 202.

A top surface 202a of the semiconductor substrate 202 is exposed to the source/drain recesses 208. In some embodiments, the etching process removes some, but not all, of the ML, such that the source/drain recesses 208 have bottoms defined by the semiconductor layer 204 or the semiconductor layer 206 in the source/drain regions 207. In some embodiments, the etching process further removes some, but not all, of the substrate portions of the fins 203, such that the source/drain recesses 208 extend below a topmost surface of the semiconductor substrate 202. In other words, the top surface 202a is below a topmost surface of the semiconductor substrate 202. The etching process can include a dry etching process, a wet etching process, other suitable etching process, or combinations thereof. In some embodiments, the etching process is a multi-step etch process. For example, the etching process may alternate etchants to separately and alternately remove the semiconductor layers 204 and the semiconductor layers 206. In some embodiments, parameters of the etching process are configured to selectively etch the ML with minimal (to no) etching of the dummy gate stack 210 and the gate spacers 212 and/or the isolation features 201. In some embodiments, a lithography process, such as those described herein, is performed to form a patterned mask layer that covers the dummy gate stack 210 and the gate spacers 212 and/or the isolation features 201, and the etching process uses the patterned mask layer as an etch mask.

The semiconductor structure 200 further includes intermix layers 205 (also referred to as “transmission layers 205”) having a mixture of materials of the semiconductor layers 204 and the semiconductor layers 206. These intermix layers 205 are shown more clearly in the enlarged view of FIG. 4B. In some embodiments, the intermix layers 205 are formed from epitaxial growing of the semiconductor layers 204 and 206. The ML can include the intermix layers 205 and core layers 206a and 204a. The core layers 206a and 204a include relatively high concentrations (e.g., greater than 90%) of materials of the semiconductor layers 204 and 206 (e.g., Si or SiGe), respectively. Each of the semiconductor layers 206 can include a core layer 206a and at least a portion of an intermix layer 205. Each of the semiconductor layers 204 can include a core layer 204a and at least a portion of an intermix layer 205.

In some embodiments, the core layer 206a is adjacent to and above the intermix layer 205. In such an intermix layer 205, a concentration of the material of the core layer 206a (e.g., Si) gradually decreases from about 90% to about 10% from top to bottom along the Z-direction, while a concentration of the material of the core layer 204a (e.g., SiGe) gradually increases from about 10% to about 90% from top to bottom along the Z-direction. In such embodiments, an atomic percentage of Ge in the intermix layer 205 gradually increases from about 0.005% to about 20% from top to bottom along the Z-direction. In some other embodiments, the core layer 204a is adjacent to and above the intermix layer 205. In such an intermix layer 205, a concentration of the material of the core layer 206a (e.g., Si) gradually increases from about 10% to about 90% from top to bottom along the Z-direction, while a concentration of the material of the core layer 204a (e.g., SiGe) gradually decreases from about 90% to about 10% from top to bottom along the Z-direction. In such embodiments, an atomic percentage of Ge in intermix layers 205 gradually decreases from about 20% to about 0.005% from top to bottom along the Z-direction. In some embodiments, the bottommost intermix layer 205 has a concentration of the material of the semiconductor substrate 202 (e.g., Si) gradually increases from about 10% to about 90% from top to bottom along the Z-direction, while a concentration of the material of the core layer 204a (e.g., SiGe) gradually decreases from about 90% to about 10% from top to bottom along the Z-direction.

In the depicted embodiment, the core layer 206a interfacing only one layer of the intermix layers 205 has a thickness T3 ranging from about 2 nm to about 12 nm, the core layer 206a interfacing two layers of the intermix layers 205 has a thickness T6 ranging from about 2 nm to about 12 nm, the core layer 204a interfacing two layers of the intermix layers 205 has a thickness T5 ranging from about 2 nm to about 12 nm, and each of the intermix layers 205 has a substantially same thickness (e.g., less than 5% difference) T4 ranging from about 0.1 nm to about 2 nm. T5 can be equal to T6. In some embodiments, T5 is different from T6.

In some embodiments, each of the semiconductor layers 204 and 206 and the intermix layers 205 have uniform profiles on each X-Y plane. For example, on an X-Y plane across one layer of the intermix layers 205, a concentration of the material of the core layer 204a (e.g., SiGe) is substantially the same. Therefore, an interface between the intermix layer 205 and the adjacent core layer 204a or 206a extends along an X-Y plane, and thicknesses of each core layers 206a or 204a are substantially the same at different locations on an X-Y plane. For example, a thickness of a core layer 206a or 204a close to a sidewall of the core layer 206a or 204a is substantially the same (e.g., less than 5% difference) as a thickness of the core layer 206a or 204a at center (the portion directly under dummy gate stack 210). Similarly, thicknesses of each intermix layers 205 are substantially the same at different locations on an X-Y plane. For example, a thickness of an intermix layer 205 close to a sidewall of the intermix layer 205 is substantially the same (e.g., less than 5% difference) as a thickness of the intermix layer 205 at center (the portion directly under dummy gate stack 210).

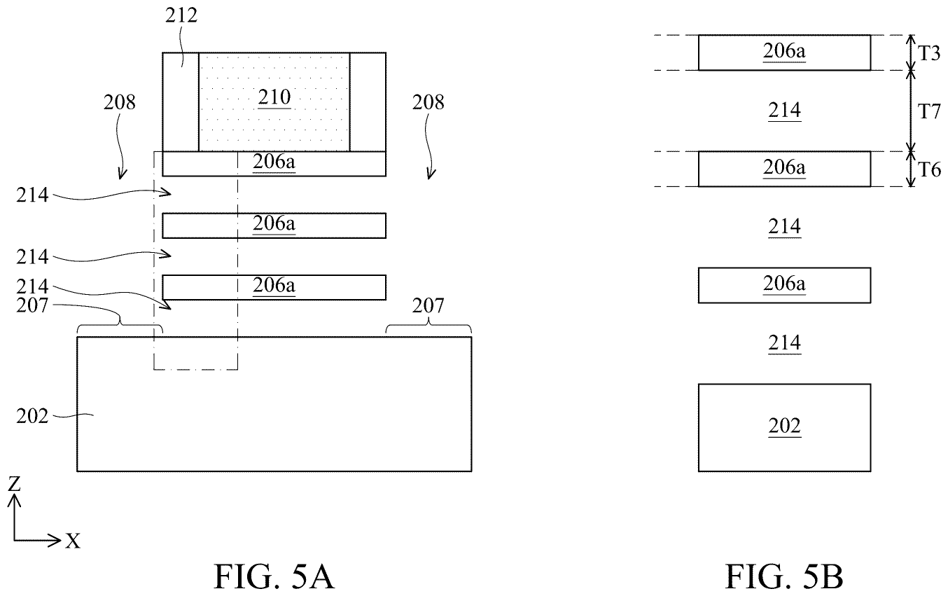

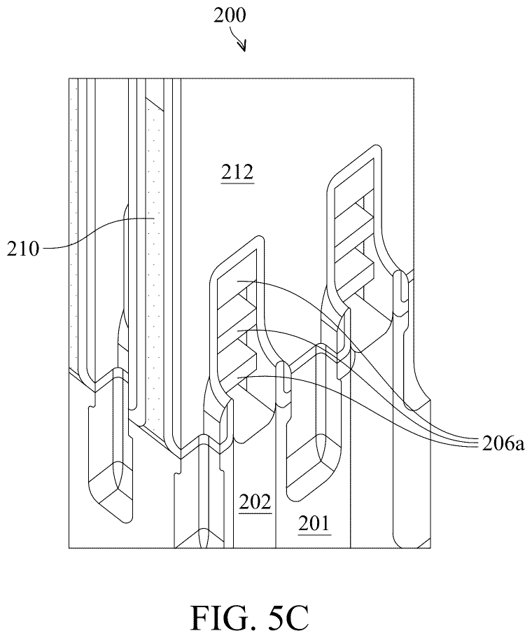

Referring now to FIGS. 5A-5C, various views of the semiconductor structure 200 are illustrated at a fabrication stage after the fabrication stage of FIGS. 4A-4C. In more detail, FIG. 5A is the X-cut cross-sectional side view of the semiconductor structure 200 taken along the cutline A-A′ of FIG. 2, FIG. 5B is the enlarged view of a portion (in the dotted rectangle) of the semiconductor structure 200 of FIG. 5A, and FIG. 5C is the three-dimensional perspective view of the semiconductor structure 200. For reasons of consistency, similar components appearing in FIGS. 5A-5C will be labeled the same unless otherwise noted.

In the fabrication stage of FIGS. 5A-5C, the semiconductor layers 204 (exposed by the source/drain recesses 208) are selectively removed from the ML, thereby forming suspended semiconductor layers 206 and openings 214 in between the vertically (e.g. in the Z-direction) adjacent semiconductor layers 206 (or the semiconductor substrate 202, where applicable). Particularly, the openings 214 are through openings that are overlapped with the core layers 204a and the intermix layers 205, and are spanning between a pair of the source/drain regions 207. FIG. 5B is an enlarged view of a portion (in the dotted rectangle) of the semiconductor structure 200 in FIG. 5A.

In the depicted embodiment, an etching process selectively etches the core layers 204a and the intermix layers 205 with minimal (to no) etching of the core layers 206a and, in some embodiments, minimal (to no) etching of the gate spacers 212. In embodiments, the core layers 206a remain unetched. In some embodiments, the semiconductor layers 204 are completely removed. In the depicted embodiment, the core layers 204a and the intermix layers 205 are completely removed, thus remaining semiconductor layers 206 only include the core layers 206a. In some other embodiments, the core layers 204a are completely removed, while the intermix layers 205 are partially removed, thus the core layers 206a and the remaining portion of the intermix layers 205 collectively form the remaining semiconductor layers 206. For case of description, regardless of whether the intermix layers 205 are completely removed, the remaining semiconductor layers 206 hereinafter are referred to as core layers 206a.

Various etching parameters can be tuned to achieve selective etching of the core layers 204a and the intermix layers 205, such as etchant composition, etching temperature, etching solution concentration, etching time, etching pressure, source power, Radio-Frequency (RF) bias voltage, RF bias power, etchant flow rate, other suitable etching parameters, or combinations thereof. For example, an etchant is selected for the etching process that etches the material of the core layers 204a (in the depicted embodiment, silicon germanium) at a higher rate than the material of the core layers 206a (in the depicted embodiment, silicon) (i.e., the etchant has a high etch selectivity with respect to the material of the core layers 204a). The intermix layers 205 include certain concentrations of the material of the core layers 204a and thus can be selectively removed with the core layers 204a.

The etching process may include a dry etching process, a wet etching process, other suitable etching process, or combinations thereof. In some embodiments, a dry etching process (such as an RIE process) utilizes a fluorine-containing gas (for example, SF₆) to selectively etch the core layers 204a and the intermix layers 205. In some embodiments, a ratio of the fluorine-containing gas to an oxygen-containing gas (for example, O₂), an etching temperature, and/or an RF power may be tuned to selectively etch silicon germanium or silicon. In some embodiments, a wet etching process utilizes an etching solution that includes ammonium hydroxide (NH₄OH) and water (H₂O) to selectively etch the core layers 204a and the intermix layers 205. In some embodiments, a chemical vapor phase etching process using hydrochloric acid (HCl) selectively etches the core layers 204a and the intermix layers 205.

In the depicted embodiment, the ML includes three suspended core layers 206a vertically stacked that will provide three channels through which current will flow between respective epitaxial source/drain features during operation of the semiconductor structure 200. The core layers 206a are thus referred to as channel layers 206a hereinafter. The channel layers 206a are separated from each other by the openings 214. The channel layers 206a are also separated from the semiconductor substrate 202 by one of the openings 214. A spacing T7 is defined between channel layers 206a along the z-direction. The spacing T7 corresponds to a dimension of the openings 214 along the Z-direction. In the depicted embodiment, the core layers 204a and the intermix layers 205 are completely removed, thus the spacing T7 is equal to (T5+2*T4), which is a sum of thicknesses of one of the core layer 204a and two intermix layers 205. In some other embodiments, the core layers 204a are completely removed while the intermix layers 205 are partially removed, thus the spacing T7 is less than (T5+2*T4). The core layers 204a and the removed intermix layers 205 can be collectively referred to as non-channel layers. In some embodiments, spacings of each openings 214 are substantially the same at different locations on an X-Y plane. For example, the spacing of an opening 214 close to an edge (e.g., a portion directly under the gate spacer 212) is substantially the same (e.g., less than 5% difference) as spacing of the opening 214 at center (e.g., a portion directly under dummy gate stack 210).

In some embodiments, the spacing T7 is within a range between about 2 nm and about 14 nm. In some embodiments, each channel layer 206a has nanometer-sized dimensions and can be referred to as a “nanowire,” which generally refers to a channel layer suspended in a manner that will allow a metal gate to physically contact at least two sides of the channel layer, and in GAA transistors, will allow the metal gate to physically contact at least four sides of the channel layer (i.e., surround the channel layer). In such embodiments, a vertical stack of suspended channel layers can be referred to as a nanostructure, and the process depicted in FIGS. 5A and 5B can be referred to as a channel nanowire release process. In some embodiments, after removing the core layers 204a and the intermix layers 205, an etching process is performed to modify a profile of the channel layers 206a to achieve desired dimensions and/or desired shapes (e.g., cylindrical-shaped (e.g., nanowire), rectangular-shaped (e.g., nanobar), sheet-shaped (e.g., nanosheet), etc.). The present disclosure further contemplates embodiments where the channel layers 206a (nanowires) have sub-nanometer dimensions depending on design requirements of semiconductor structure 200.

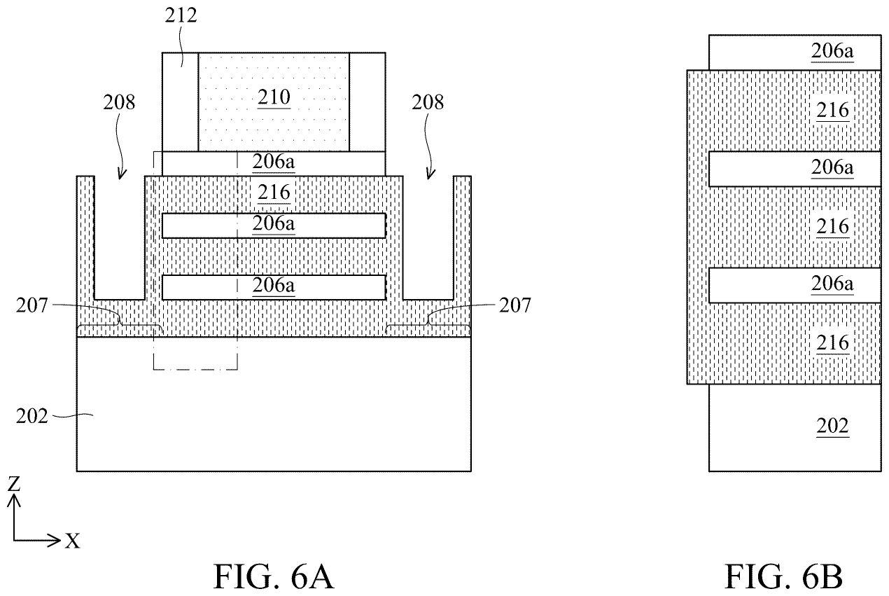

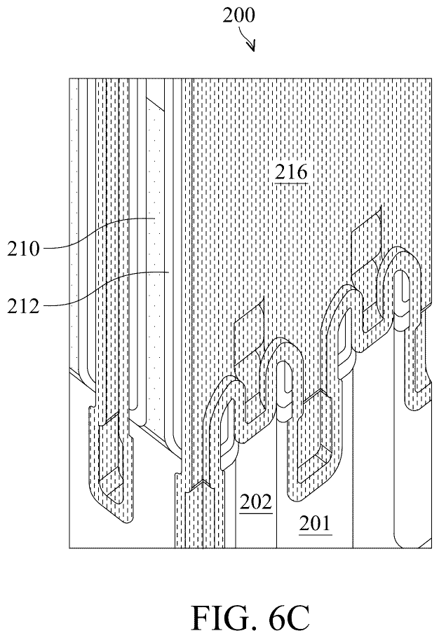

Referring now to FIGS. 6A-6C, various views of the semiconductor structure 200 are illustrated at a fabrication stage after the fabrication stage of FIGS. 5A-5C. In more detail, FIG. 6A is the X-cut cross-sectional side view of the semiconductor structure 200 taken along the cutline A-A′ of FIG. 2, FIG. 6B is the enlarged view of a portion (in the dotted rectangle) of the semiconductor structure 200 of FIG. 6A, and FIG. 6C is the three-dimensional perspective view of the semiconductor structure 200. For reasons of consistency, similar components appearing in FIGS. 6A-6C will be labeled the same unless otherwise noted.

In the fabrication stage of FIGS. 6A-6C, a dielectric material 216 is deposited into the opening 214 and conformally over the source/drain regions 207. FIG. 6B is an enlarged view of a portion (in the dotted rectangle) of the semiconductor structure 200 in FIG. 6A. The depositing the dielectric material can include any suitable methods, such as atomic layer deposition (ALD), plasma enhanced atomic layer deposition (PEALD), physical vapor deposition (PVD), or combinations thereof. In some embodiments, the depositing the dielectric material include an atomic layer deposition (ALD) process. The conformally depositing the dielectric material 216 can form a layer of the dielectric material 216 of a thickness of about 2 nm to about 14 nm. In some embodiments, the thickness is about 2 nm to about 7 nm. In some embodiments, the thickness is about 2 nm to about 5 nm.

The dielectric material 216 can include any suitable materials that have an etching selectively different from the channel layers 206a. In some embodiments, the dielectric material 216 include an oxide material. The dielectric material 216 can include at least one of silicon oxide (SiO₂, SiO), silicon oxynitride (SiON), aluminum oxide (Al₂O₃), silicon nitride, SiOC, SiOCN, and a combination thereof. In some embodiments, the dielectric material 216 includes a composition different from the semiconductor layers 204. In some embodiments, the dielectric material 216 includes less than 0.001% (atomic percentage) of germanium (Ge) or is free of Ge. In some embodiments, the dielectric material 216 is free of SiGe. If the Ge level in the dielectric material 216 is too high (e.g., greater than 1% atomic percentage), the following processes may be impacted by the Ge residue, which will be described in following descriptions.

In some embodiments, unlike the semiconductor layers 204 and 206, the channel layers 206a and the adjacent dielectric material 216 have clear boarders that are free of intermix sessions, which may include a mixture of materials of the channel layers 206a and the dielectric material 216. The channel layers 206a remain substantially unchanged (e.g., less than 5% changes) during the following processes, which will be described in further detail below.

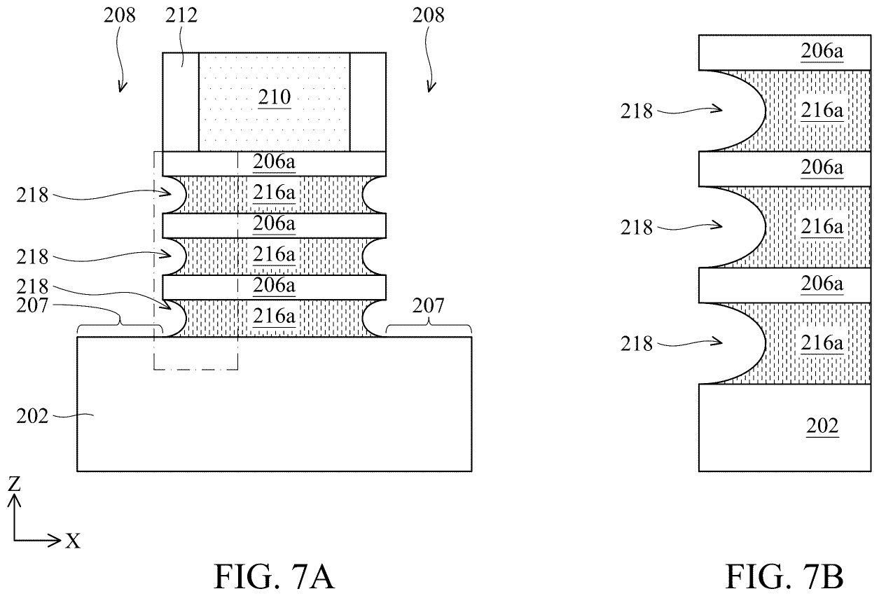

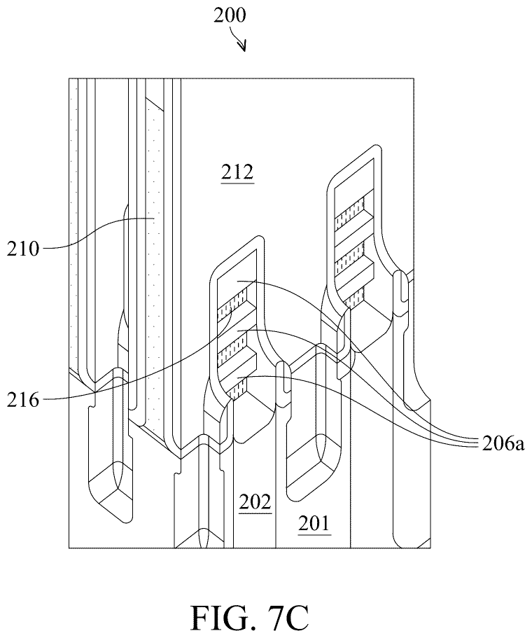

Referring now to FIGS. 7A-7C, various views of the semiconductor structure 200 are illustrated at a fabrication stage after the fabrication stage of FIGS. 6A-6C. In more detail, FIG. 7A is the X-cut cross-sectional side view of the semiconductor structure 200 taken along the cutline A-A′ of FIG. 2, FIG. 7B is the enlarged view of a portion (in the dotted rectangle) of the semiconductor structure 200 of FIG. 7A, and FIG. 7C is the three-dimensional perspective view of the semiconductor structure 200. For reasons of consistency, similar components appearing in FIGS. 7A-7C will be labeled the same unless otherwise noted.

In the fabrication stage of FIGS. 7A-7C, the dielectric material 216 in the source/drain regions 207 is removed, and portions of the dielectric material 216 between the adjacent channel layers 206a (or the semiconductor substrate 202, where applicable) are recessed through exposed sidewall surfaces in the source/drain regions 207 via a selective etching process to form undercuts 218 and dielectric layers 216a (or dielectric interposers 216a). FIG. 7B is an enlarged view of a portion (in the dotted rectangle) of the semiconductor structure 200 in FIG. 7A.

The selective etching process may be any suitable processes, such as a wet etching or a dry etching process. The extent to which the dielectric material 216 are recessed (or the size of the portion removed) is determined by the processing conditions such as the duration the dielectric material 216 is exposed to an etching chemical. In the depicted embodiments, the duration is controlled such that the dielectric material 216 in the source/drain regions 207 is completely removed, and side portions of the dielectric material 216 between adjacent channel layers 206a (or the semiconductor substrate 202, where applicable) are removed, while center portions (e.g., the dielectric layer 216a) of the dielectric material 216 between the adjacent channel layers 206a (or the semiconductor substrate 202, where applicable) remain substantially unchanged. As illustrated in FIG. 7B, the selective etching process creates the undercuts 218, which extend the source/drain recesses 208 into areas beneath the channel layers 206a and the gate spacers 212.

In some embodiments, the undercuts 218 have a convex shape as depicted in FIG. 7B. In some embodiments, the dielectric layers 216a include tip portions extending towards sidewalls of the channel layers 206a (or the semiconductor substrate 202, where applicable). In some embodiments, the tip portions extend to directly contact an entirety of a top or a bottom surface of a channel layer 206a (or the semiconductor substrate 202, where applicable). In such embodiments, the dielectric layers 216a have a sidewall coplanar with a sidewall of the channel layers 206a.

Meanwhile, the channel layers 206a are only slightly affected during the selective etching process. For example, prior to the selective etching process, side portions of the channel layers 206a each has a thickness T3 or T6 (see FIG. 5B). After the selective etching process, thicknesses of the side portions of the channel layers 206a may have about 1% to 5% change from T3 or T6. The etch selectivity between the channel layers 206a and the dielectric material 216 is made possible by the different material compositions between these layers. For example, the dielectric material 216 may be etched away at a substantially faster rate (e.g. more than about 5 times faster or about 10 times faster) than the channel layers 206a. Because spacings of each openings 214 as in FIGS. 5A-5B are substantially the same at different locations on an X-Y plane, and the channel layers 206a (or the semiconductor substrate 202, where applicable) remain substantially unchanged (e.g., less than 5% changes), spacing of each undercuts 218 along the Z-direction is substantially the same as a thickness of each of the dielectric layers 216a (e.g., less than 5% difference), which is about the same as T7.

As discussed above, the selective etching process may be a wet etching process in some embodiments. The etching technique and etchant(s) may be selected to etch the dielectric material 216 without significant etching of the surrounding structures, such as the channel layers 206a. In an embodiment, the channel layers 206a include Si and the dielectric material 216 include an oxide material (e.g., silicon oxide). In an embodiment, a hydrofluoric acid (HF) solution, such as a dilute hydrofluoric acid (DHF), may be used to selectively etch away the dielectric material 216. For example, the dielectric material 216 may be etched away at a substantially faster rate than the channel layers 206a (e.g., with a selectivity greater than 10). As a result, desired portions of the dielectric material 216 (e.g. the side portions of the dielectric material 216 between the adjacent channel layers 206a (or the semiconductor substrate 202, where applicable)) are removed, while the channel layers 206a remain substantially unchanged. The etching duration is adjusted such that the size of the removed portions of the dielectric material 216 are controlled. The optimal condition may be reached by additionally adjusting the etching temperature, dopant concentration, as well as other experimental parameters.

In some embodiments, the selective etching process may include a dry, plasma-free etching process performed using a suitable etch system, such as CERTAS® Gas Chemical Etch System, available from Tokyo Electron Limited, Tokyo, Japan. In some examples, the selective etching process may include etching using a standard clean 1 (SC-1) solution, a solution of ammonium hydroxide (NH₄OH), hydrogen peroxide (H₂O₂) and water (H₂O), hydrofluoric acid (HF), buffered HF, and/or a fluorine (F₂)-based etch. In some examples, the F₂-based etch may include an F₂ remote plasma etch.

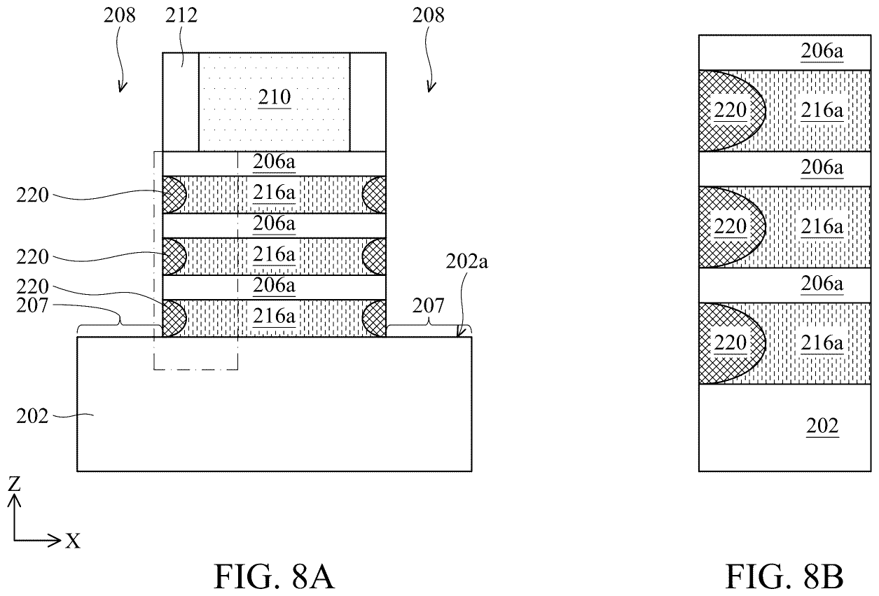

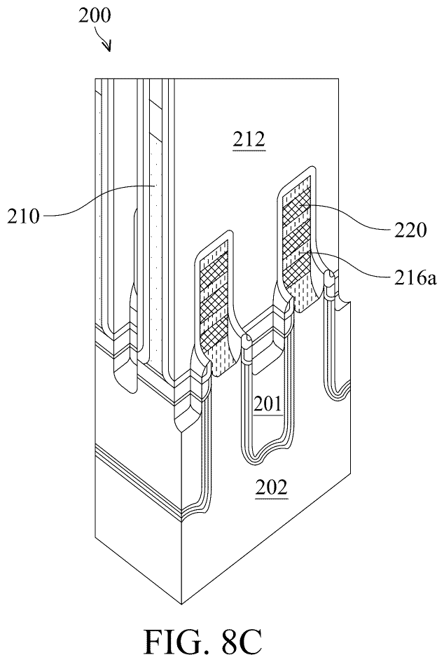

Referring now to FIGS. 8A-8C, various views of the semiconductor structure 200 are illustrated at a fabrication stage after the fabrication stage of FIGS. 7A-7C. In more detail, FIG. 8A is the X-cut cross-sectional side view of the semiconductor structure 200 taken along the cutline A-A′ of FIG. 2, FIG. 8B is the enlarged view of a portion (in the dotted rectangle) of the semiconductor structure 200 of FIG. 8A, and FIG. 8C is the three-dimensional perspective view of the semiconductor structure 200. For reasons of consistency, similar components appearing in FIGS. 8A-8C will be labeled the same unless otherwise noted.

In the fabrication stage of FIGS. 8A-8C, a second dielectric material is deposited into the undercuts 218. Deposition of the second dielectric material forms a spacer layer over the dummy gate stack 210, the gate spacers 212, and over features defining the source/drain recesses 208 (e.g., the channel layers 206a, the dielectric layers 216a, and the semiconductor substrate 202), and includes methods such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the source/drain recesses 208. The deposition process is configured to ensure that the spacer layer fills the undercuts 218. An etching process is then performed that selectively etches the spacer layer to form inner spacers 220 as depicted in FIGS. 8A-8B with minimal (to no) etching of the channel layers 206a, the dummy gate stack 210, and the gate spacers 212. In some embodiments, the spacer layer is removed from sidewalls of the gate spacers 212, sidewalls of the channel layers 206a, the dummy gate stack 210, and the semiconductor substrate 202. The spacer layer (and thus inner spacers 220) includes a material that is different than a material of the channel layers 206a and a material of the gate spacers 212 to achieve a desired etching selectivity during the etching process. In some embodiments, the spacer layer includes a material that is different than a material of the dielectric layers 216a. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material, such as those described herein. In some embodiments, dopants (for example, p-type dopants, n-type dopants, or combinations thereof) are introduced into the dielectric material, such that the spacer layer includes a doped dielectric material.

In embodiments, the inner spacers 220 fill the undercuts 218 and thus have a convex shape as depicted in FIG. 8B. In such embodiments, the dielectric layers 216a include tip portions between the inner spacers 220 and the channel layers 206a (or semiconductor substrate 202, where applicable). In some embodiments, the tip portions extend towards a sidewall of the ML but are not exposed to the source/drain recesses 208. In such embodiments, the inner spacers 220 separate the dielectric layers 216a from the source/drain recesses 208. In some other embodiments, although not depicted, the tip portions extend to directly contact an entirety of a top and/or a bottom surface of the channel layers 206a (or the semiconductor substrate 202, where applicable). In such embodiments, the dielectric layers 216a are exposed to the source/drain recesses 208 and separate the adjacent inner spacer 220 from the adjacent channel layers 206a (or the semiconductor substrate 202, where applicable). The dielectric layers 216a can have a sidewall coplanar with a sidewall of the channel layers 206a.

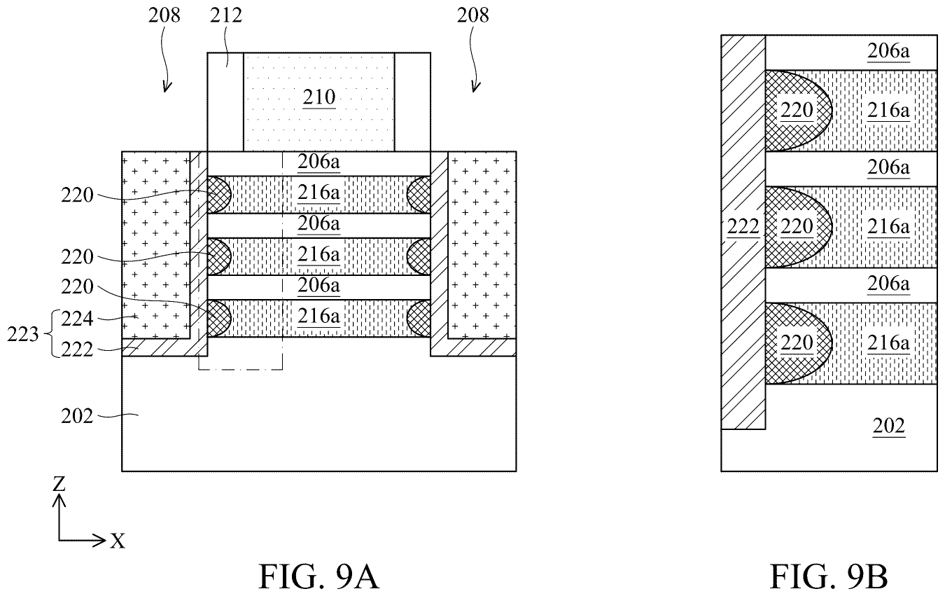

Referring to FIGS. 9A-9B, epitaxial source/drain features 223 are formed in the source/drain recesses 208. FIG. 9B is an enlarged view of a portion (in the dotted rectangle) of the semiconductor structure 200 in FIG. 9A. In some embodiments, one source/drain feature 223 is a source electrode, and the other source/drain feature 223 is a drain electrode. The channel layers 206a that extend from one source/drain feature 223 to the other source/drain feature 223 may form channels of the semiconductor structure 200. Multiple processes including etching and growth processes may be employed to grow the epitaxial source/drain features 223. Each of the epitaxial source/drain features 223 can include multiple layers, such as a first source/drain layer 222 and a second source/drain layer 224. In the depicted embodiment, the epitaxial source/drain features 223 have top surfaces that are substantially aligned with a top surface of the topmost channel layer 206a. However, in other embodiments, the epitaxial source/drain features 223 may alternatively have top surfaces that extend higher than the top surface of the topmost channel layer 206a (e.g. in the Z-direction). In the depicted embodiment, the epitaxial source/drain features 223 occupy a lower portion of the source/drain recesses 208 (e.g. the portion defined by the inner spacers 220 and the channel layers 206a), leaving an upper portion of the source/drain recesses 208 (e.g. the portion defined by the gate spacers 212) open. In some embodiments, the epitaxial source/drain features 223 may merge together, for example, along the X-direction, to provide a larger lateral width than an individual epitaxial feature.

The epitaxial source/drain features 223 may include any suitable semiconductor materials. For example, the epitaxial source/drain features 223 in an n-type GAA device may include Si, SiC, SiP, SiAs, SiPC, or combinations thereof; while the epitaxial source/drain features 223 in a p-type GAA device may include Si, SiGe, Ge, SiGeC, or combinations thereof. The epitaxial source/drain features 223 may be doped in-situ or ex-situ. For example, the epitaxially grown Si source/drain features may be doped with carbon to form silicon:carbon (Si:C) source/drain features, phosphorous to form silicon:phosphor (Si:P) source/drain features, or both carbon and phosphorous to form silicon carbon phosphor (SiCP) source/drain features; and the epitaxially grown SiGe source/drain features may be doped with boron. One or more annealing processes may be performed to activate the dopants in the epitaxial source/drain features 223. The annealing processes may include rapid thermal annealing (RTA) and/or laser annealing processes.

The epitaxial source/drain features 223 may directly interface with sidewalls of the inner spacers 220 and the channel layers 206a. During the epitaxial growth, semiconductor materials grow from the exposed top surface 202a of the semiconductor substrate 202 (e.g., the exposed top surface of doped region) as well as from the exposed side surfaces of the channel layers 206a. It is noted that semiconductor materials do not grow from the surfaces of the inner spacers 220 and the gate spacers 212 during the epitaxial growth process.

Because the semiconductor layers 204 and the intermix layers 205 have been removed, SiGe in the ML when forming the epitaxial source/drain features 223 is negligible (e.g., less than 0.0001% of the total SiGe in the semiconductor layers 204), doping diffusion to undesired regions is reduced, and built-in stress (e.g., tensile stress and compressive stress) during processes is reduced as well.

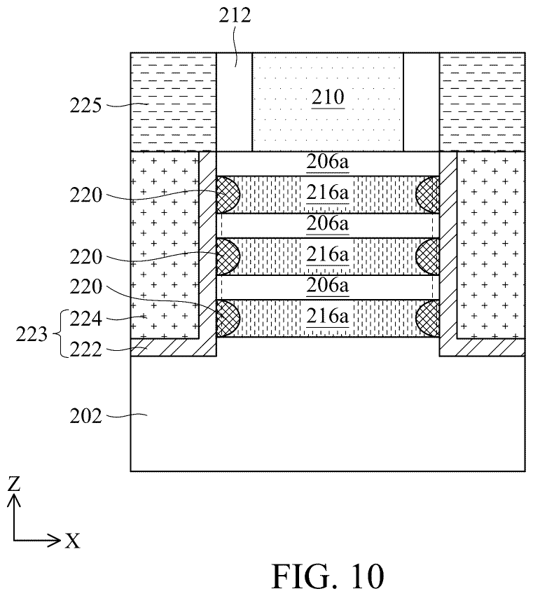

Referring to FIG. 10, an interlayer dielectric (ILD) layer 225 is formed over the epitaxial source/drain features 223 in the remaining spaces of the source/drain recesses 208, as well as vertically over the isolation features 201. The ILD layer 225 may also be formed in between the adjacent dummy gate stacks 210 along the Y-direction, and in between the source/drain features 223 along the X-direction. The ILD layer 225 may include a dielectric material, such as a high-k material, a low-k material, or an extreme low-k material. For example, the ILD layer 225 may include SiO₂, SiOC, SiON, or combinations thereof. The ILD layer 225 may include a single layer or multiple layers, and may be formed by a suitable technique, such as CVD, ALD, and/or spin-on techniques. In some embodiments, a contact etch-stop layer (CESL) is disposed between the ILD layer 225 and the isolation features 201, the epitaxial source/drain features 223 and the gate spacers 212. The CESL includes a material different than the ILD layer 225, such as a dielectric material that is different than the dielectric material of the ILD layer 225 to achieve the etch selectivity. For example, where the ILD layer 225 includes a low-k dielectric material, the CESL includes silicon and nitrogen, such as silicon nitride or silicon oxynitride. Subsequent to the deposition of the ILD layer 225 and/or the CESL, a CMP process and/or other planarization process can be performed to remove excessive portions of the ILD layer 225, thereby planarizing a top surface of the ILD layer 225, until reaching (exposing) a top portion (or top surface) of the dummy gate stack 210. Among other functions, the ILD layer 225 provides electrical isolation between the various components of the semiconductor structure 200.

The ILD layer 225 may be a portion of a multilayer interconnect (MLI) feature disposed over the semiconductor substrate 202. The MLI feature electrically couples various devices (for example, a GAA transistor of the semiconductor structure 200, transistors, resistors, capacitors, and/or inductors) and/or components (for example, gate structures and/or epitaxial source/drain features of GAA transistors), such that the various devices and/or components can operate as specified by design requirements of the semiconductor structure 200. The MLI feature includes a combination of dielectric layers and electrically conductive layers (e.g., metal layers) configured to form various interconnect structures. The conductive layers are configured to form vertical interconnect features, such as device-level contacts and/or vias, and/or horizontal interconnect features, such as conductive lines. Vertical interconnect features typically connect horizontal interconnect features in different layers (or different planes) of the MLI feature. During operation, the interconnect features are configured to route signals between the devices and/or the components of the semiconductor structure 200 and/or distribute signals (for example, clock signals, voltage signals, and/or ground signals) to the devices and/or the components of the semiconductor structure 200.

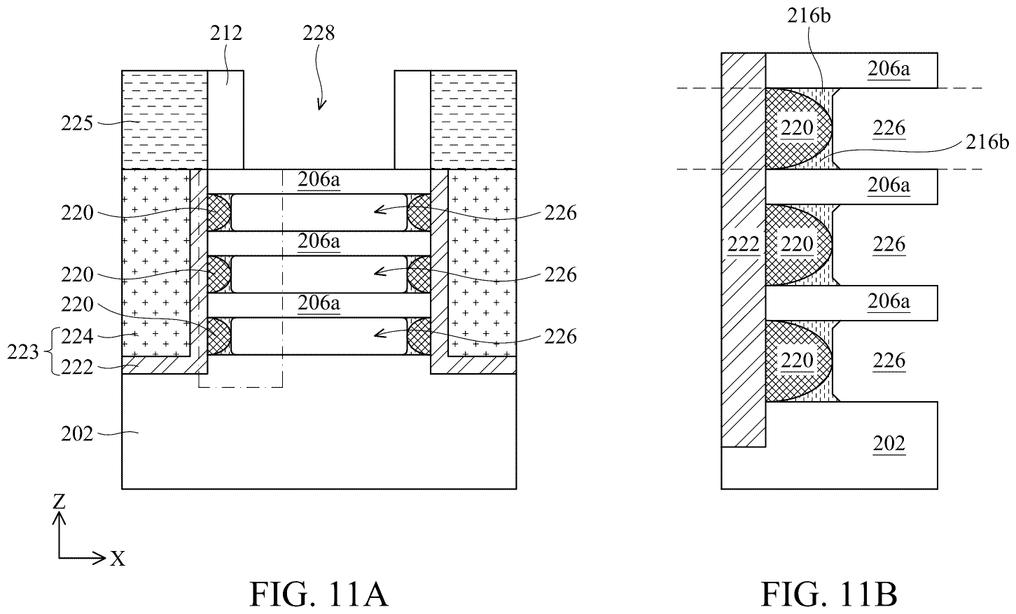

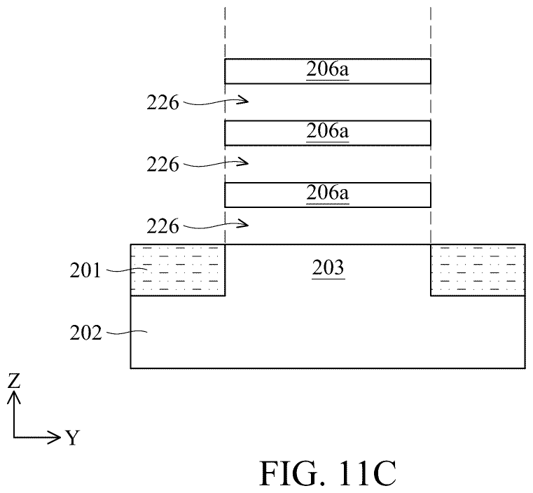

Referring to FIGS. 11A-11C, the dummy gate stack 210 is selectively removed through any suitable lithography and etching processes. In some embodiments, the lithography process includes forming a photoresist layer (resist), exposing the resist to a pattern, performing a post-exposure bake process, and developing the resist to form a masking element, which exposes a region including the dummy gate stack 210. Then, the dummy gate stack 210 is selectively etched through the masking element. In some other embodiments, the gate spacers 212 may be used as the masking element or a part thereof. For example, the dummy gate stack 210 may include polysilicon, the gate spacers 212 and the inner spacers 220 may include dielectric materials, and the channel layers 206a include a semiconductor material. Therefore, an etch selectivity may be achieved by selecting appropriate etching chemicals, such that the dummy gate stack 210 may be removed without substantially affecting the features of the semiconductor structure 200. The removal of the dummy gate stack 210 creates gate trench 228. The gate trench 228 exposes the top surfaces and the side surfaces of the stack of the channel layers 206a and the dielectric layers 216a. In other words, the channel layers 206a and the dielectric layers 216a are exposed at least on two side surfaces in the gate trench 228. Additionally, the gate trench 228 also exposes the top surfaces of the isolation features 201.

Referring to FIGS. 11A-11C, the dielectric layers 216a are also selectively removed through the gate trench 228, for example using wet or dry etching process. The etching chemical is selected such that the dielectric layers 216a have a sufficiently different etching rate as compared to the channel layers 206a, the inner spacers 220, and the gate spacers 212. As a result, the channel layers 206a, the inner spacers 220, and the gate spacers 212 remain substantially unchanged. This selective etching process may include one or more etching steps.

As illustrated in FIGS. 11A-11C, in the present embodiment, the removal of the dielectric layers 216a forms suspended channel layers 206a and openings 226 in between the vertically adjacent layers (e.g. in the Z-direction), thereby exposing the top and bottom surfaces of the channel layers 206a. Each of the channel layers 206a are now exposed circumferentially in the X-Z plane. In addition, the portion of the doped regions of the semiconductor substrate 202 beneath the channel layers 206a are also exposed in the openings 226.

In the examples depicted in FIGS. 11A-11C, the gate trench 228 and the openings 226 vertically adjacent to the gate trench 228 (e.g. in the Z-direction) collectively form an opening having a vertical profile. In other words, the opening collectively formed by the gate trench 228 and its corresponding openings 226 have vertical sidewalls. In some embodiments, such openings having the vertical sidewalls may be formed by a plurality of etch processes. For example, the etch chemistry of the etch process used to remove the dummy gate stack 210 and thereby form the gate trench 228 may include hydrogen bromide (HBr) combined with chlorine (Cl₂), tetrafluoromethane (CF₄), oxygen, or a combination thereof. Furthermore, the etch process used to selectively remove the dielectric layers 216a and thereby form the openings 226 may have an initial etch chemistry including hydrogen bromide (HBr) combined with chlorine (Cl₂), oxygen, or a combination thereof. This initial etch chemistry is followed by a subsequent etch chemistry including hydrogen bromide (HBr) combined with tetrafluoromethane (CF₄), oxygen, or a combination thereof that induces the vertical profile of the opening collectively formed by the gate trench 228 and its corresponding openings 226.

FIG. 11B is an enlarged view of a portion (in the dotted rectangle) of the semiconductor structure 200 in FIG. 11A. In some embodiments, the removal process only removes some, but not all, of the dielectric layers 216a. A portion of the dielectric layers 216a may remain between the inner spacers 220 and the channel layers 206a (or the semiconductor substrate 202, where applicable). Such remaining portion can be referred to as “remaining dielectric layers 216b.”

In some embodiments, the remaining dielectric layers 216b are free of SiGe. In conventional processes, non-channel layers including SiGe are commonly used. After forming epitaxial source/drain features, most of non-channel layers are removed while SiGe residue can remain between adjacent channel layers, causing undesired capacitance between the SiGe residue and adjacent conductive features. In the present disclosure, the semiconductor layers 204 and the intermix layers 205 have been removed, thus SiGe in the ML is negligible (e.g., less than 0.0001% of the total SiGe in the semiconductor layers 204). Therefore, the capacitance between SiGe and other conductive features (e.g., the epitaxial source/drain features 223) is reduced or negligible.

In some embodiments, an etching selectivity of the dielectric layers 216a to the channel layers 206a can be higher than an etching selectivity of the semiconductor layers 204 to the channel layers 206a in conventional processes. In some embodiments, in the removing of the dielectric layers 216a, an etching selectivity of the dielectric layers 216a to the channel layers 206a is greater than 10. If the etching selectivity of the dielectric layers 216a to the channel layers 206a is too small, the channel layers 206a may be etched, thus thicknesses and/or widths of the channel layers 206a may be reduced, which may impact performance of the semiconductor structure 200 (e.g., more SCEs, higher capacitance).

FIG. 11C is a cross-sectional view of the semiconductor structure 200 in FIG. 11A and along the line B-B′ in FIG. 2, and it may also be referred to as a Y-cut view. In some embodiments, the channel layers 206a has no or little width loss during the removal of the dielectric layers 216a. This can result from the etching selectivity of the dielectric layers 216a to the channel layers 206a, and/or that the channel layers 206a and the adjacent dielectric material 216 have clear boarders that are free of intermix session, as described above. In some embodiments, the channel layers 206a have a width along the X-direction that is equal to or less than a width of a bottom portion of the fin 203 (e.g., a portion of fin 203 contacting the semiconductor substrate 202) along the X-direction by less than 2%. In other words, the width loss of the channel layers 206a in the process is negligible, which improves device performance and reduces capacitance.

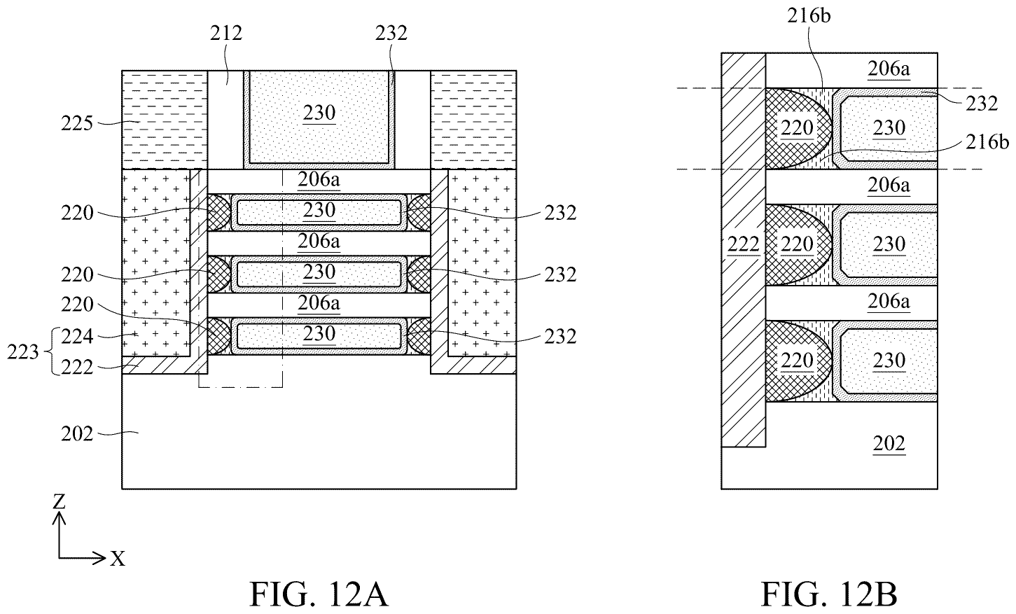

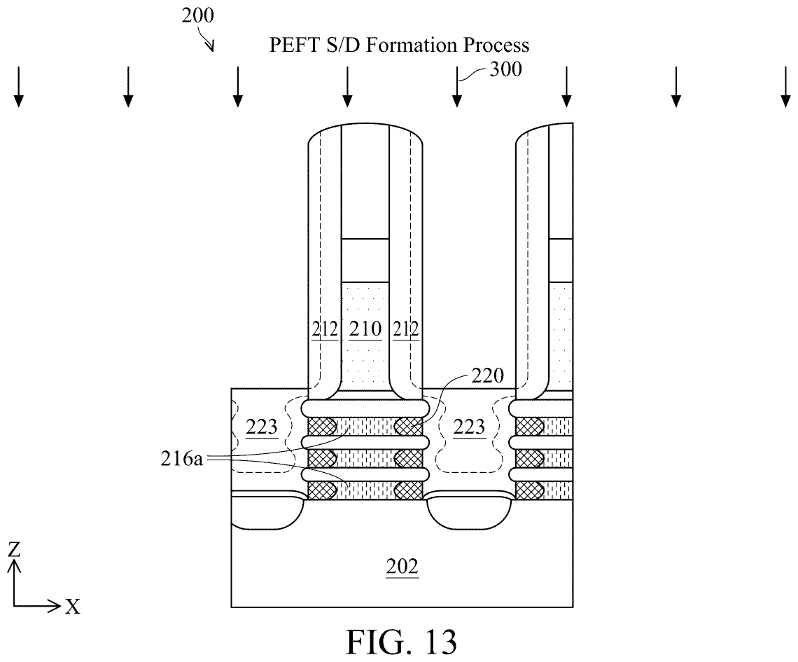

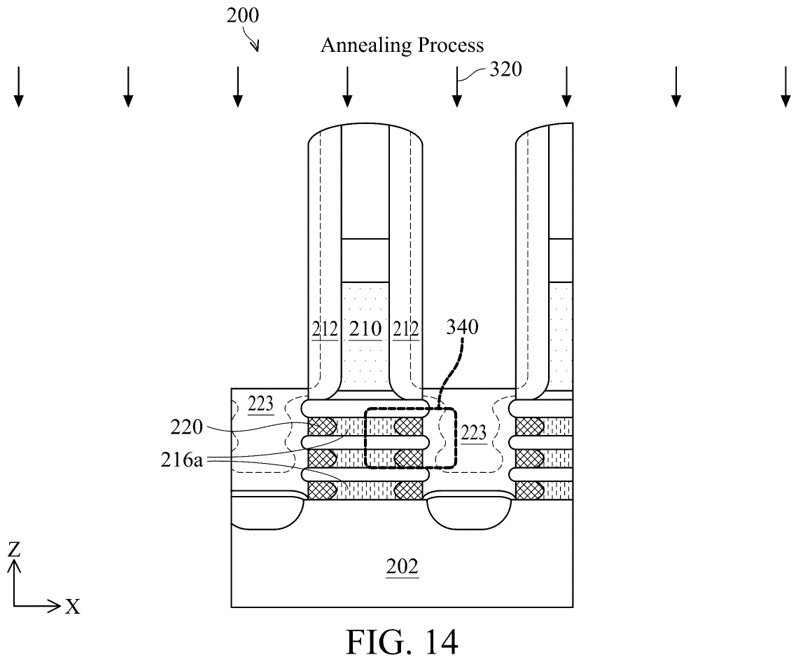

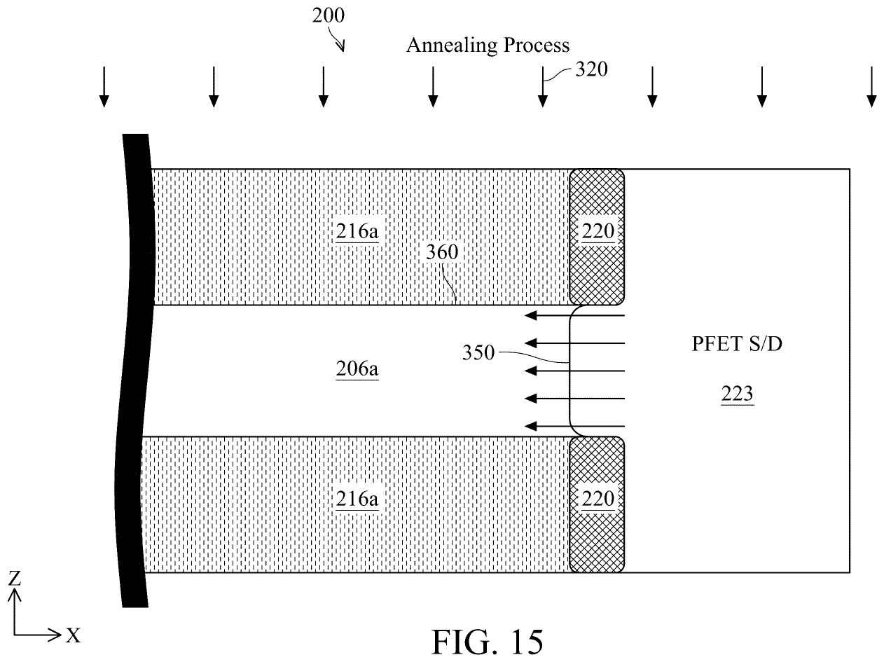

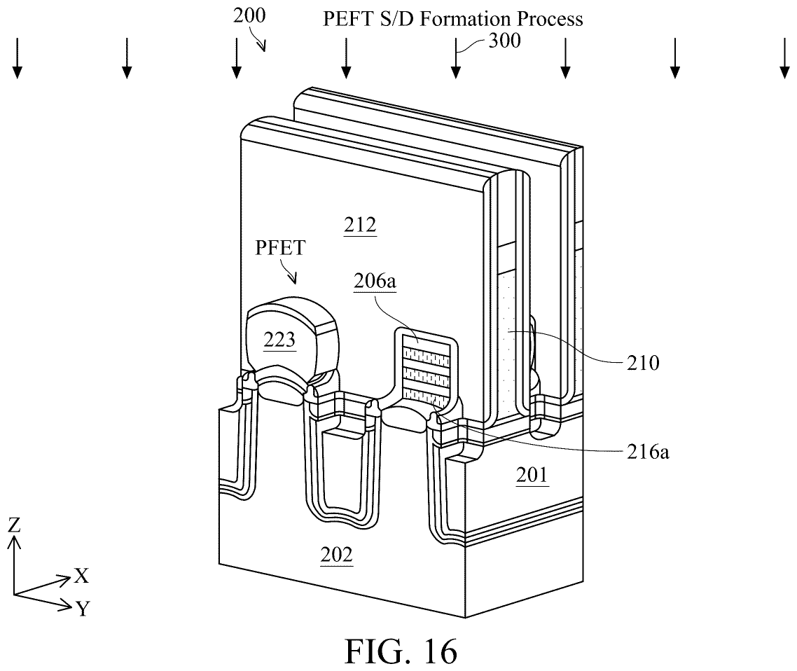

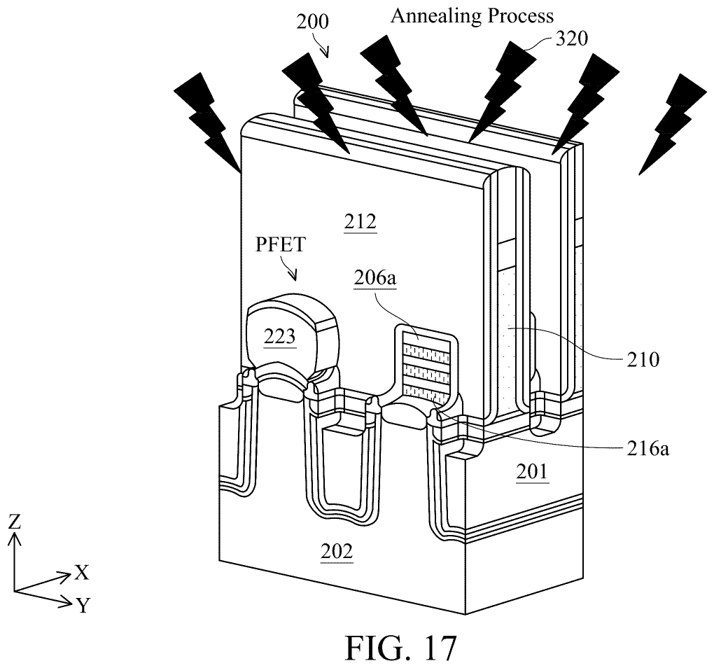

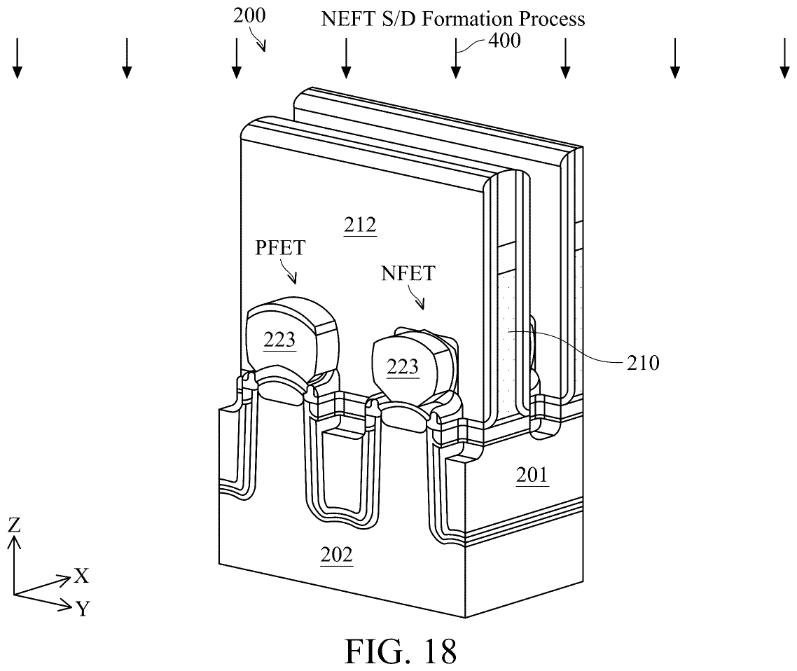

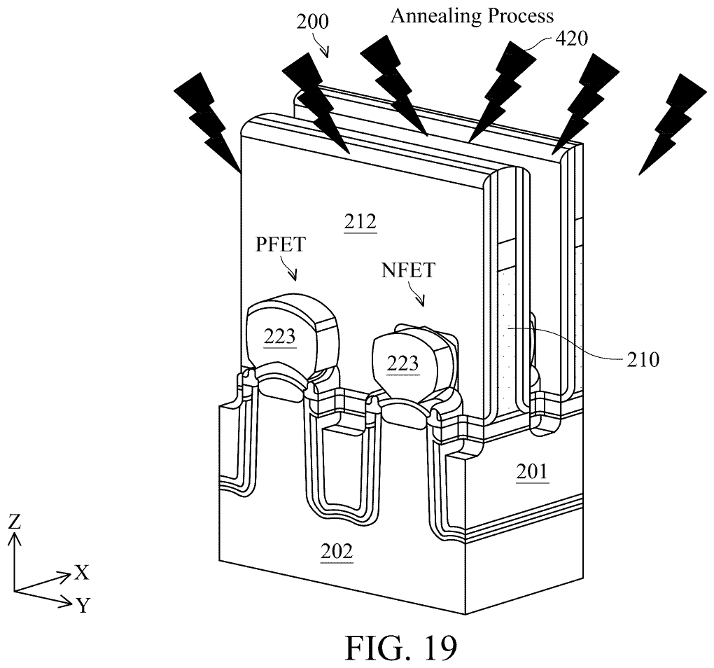

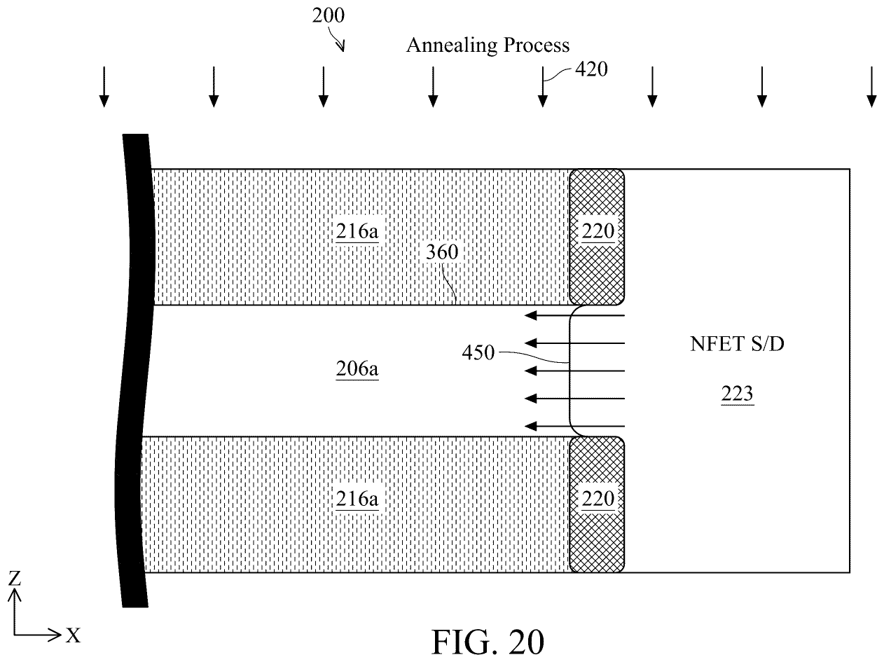

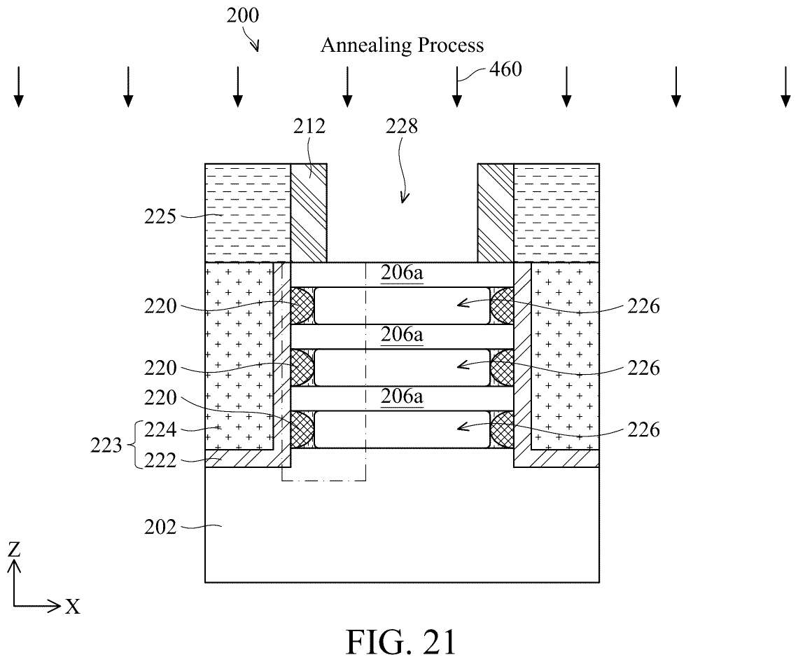

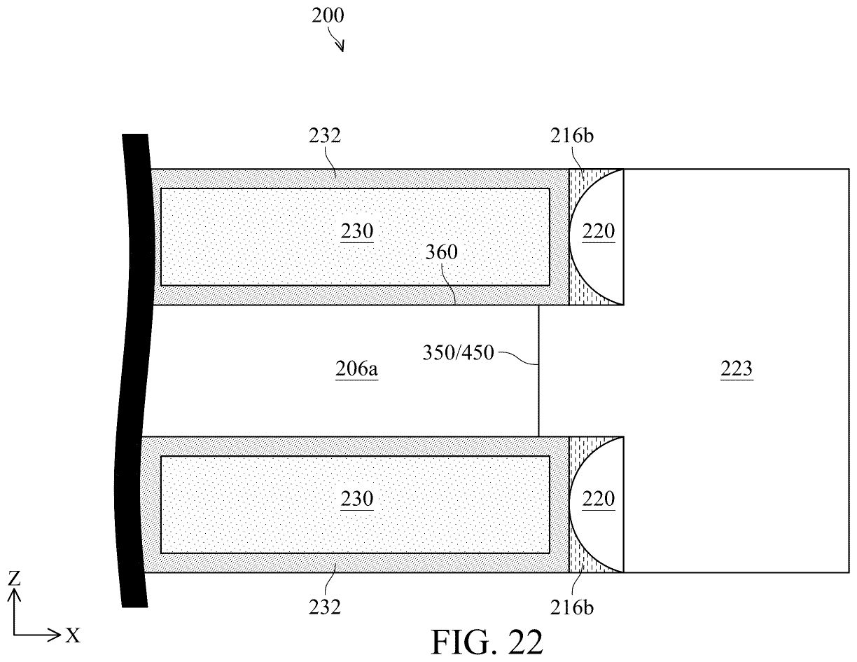

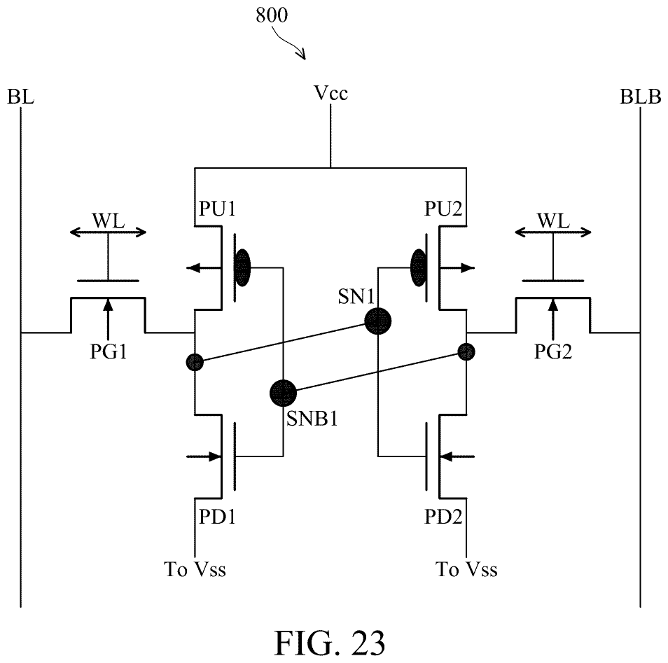

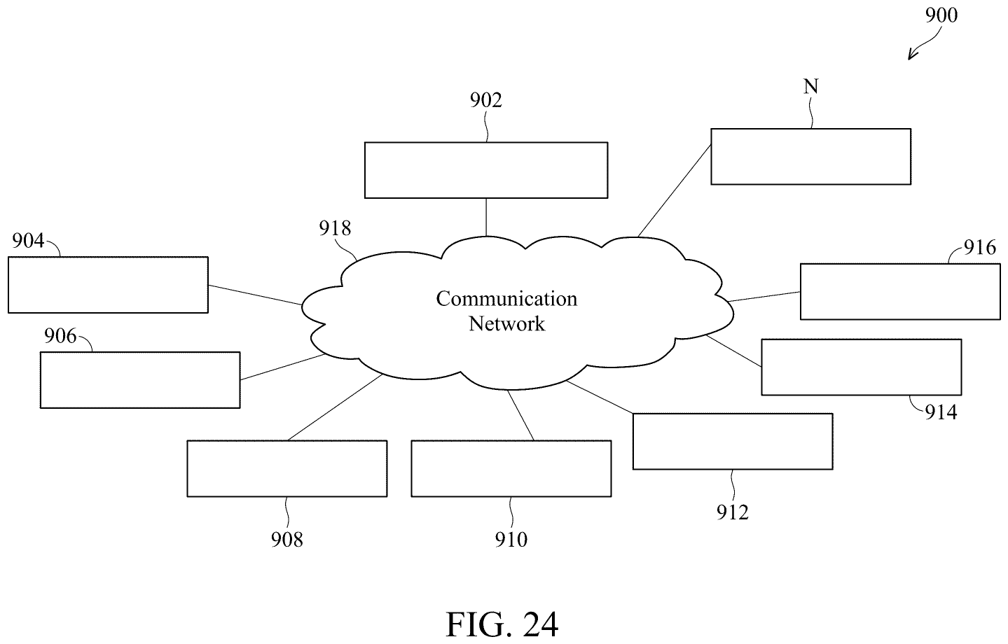

Referring to FIGS. 12A-12B, a metal gate stack is formed. The metal gate stack includes a gate dielectric layer 232 and a gate electrode 230 disposed over the gate dielectric layer 232. For example, the metal gate stack may include a polysilicon gate electrode over a SiON gate dielectric layer. As another example, the metal gate stack may include a metal gate electrode over a high-k dielectric layer. In some instances, a refractory metal layer may interpose between the metal gate electrode (such as an aluminum gate electrode) and the high-k dielectric layer. As yet another example, the metal gate stack may include silicide. The gate dielectric layer 232 is formed between the gate electrode 230 and the channels formed by the channel layers 206a.

In some embodiments, the gate dielectric layer 232 is formed conformally on the semiconductor structure 200. The gate dielectric layer 232 at least partially fills the gate trenches 228. In some embodiments, dielectric interfacial layers may be formed over the channel layers 206a prior to forming the gate dielectric layer 232. Such dielectric interfacial layers improve the adhesion between the channel layers 206a and the gate dielectric layer 232. In the examples depicted in this disclosure, such dielectric interfacial layers are omitted. Instead, in the embodiments shown, the gate dielectric layer 232 is formed around the exposed surfaces of each of the channel layers 206a, such that it wraps around the channel layers 206a in 360 degrees. Additionally, the gate dielectric layer 232 also directly contacts vertical sidewalls of the inner spacers 220, sidewalls of the remaining dielectric layers 216b, and vertical sidewalls of the gate spacers 212. The gate dielectric layer 232 may include a dielectric material having a dielectric constant greater than a dielectric constant of SiO₂, which is approximately 3.9. For example, the gate dielectric layer 232 may include hafnium oxide (HfO₂), which has a dielectric constant in a range from about 18 to about 40. As various other examples, the gate dielectric layer 232 may include ZrO₂, Y₂O₃, La₂O₅, Gd₂O₅, TiO₂, Ta₂O₅, HfErO, HfLaO, HfYO, HfGdO, HfAlO, HfZrO, HfTIO, HfTaO, SrTiO, or combinations thereof. The formation of the gate dielectric layer 232 may be by any suitable processes, such as CVD, PVD, ALD, or combinations thereof.

After forming the gate dielectric layer 232, the gate electrode 230 is formed over the gate dielectric layer 232 to fill the remaining spaces of the gate trenches 228. The gate electrode 230 may include any suitable materials, such as titanium nitride (TiN), tantalum nitride (TaN), titanium aluminide (TiAl), titanium aluminum nitride (TiAlN), tantalum aluminide (TaAl), tantalum aluminum nitride (TaAlN), tantalum aluminum carbide (TaAlC), tantalum carbonitride (TaCN), aluminum (Al), tungsten (W), copper (Cu), cobalt (Co), nickel (Ni), platinum (Pt), or combinations thereof. In some embodiments, a CMP is performed to expose a top surface of the ILD layer 225. The gate dielectric layer 232 and the gate electrode 230 collectively form the metal gate stack, which engages multiple layers within the channel layers 206a (e.g. multiple nanochannels).

FIG. 12B is an enlarged view of a portion (in the dotted rectangle) of the semiconductor structure 200 in FIG. 12A. As previously described in this disclosure, thicknesses along the Z-direction of each channel layers 206a are substantially the same at different locations on an X-Y plane, and the channel layers 206a are substantially unchanged through the process, thus after forming the metal gate stack, thicknesses along the Z-direction of each channel layers 206a remain substantially the same (e.g., less than 5% difference) at different locations on an X-Y plane. If the thicknesses along the Z-direction of each channel layers 206a are not substantially the same (e.g., less than 5% difference) at different locations on an X-Y plane, for example, a thickness on edges (e.g., closer to epitaxial source/drain features) is greater than 10% of a thickness in center (e.g., directly under the metal gate stack above the ML), undesired capacitance may increase. In conventional processes, non-channel layers including SiGe are commonly removed after forming epitaxial source/drain features and before forming the metal gate stack, and the removing of the non-channel layers include multiple etching steps for removal of intermix layers. These multiple etching steps may cause a width reduction of channel layers (e.g., width along x direction) and thicker channel layers on edges (e.g., closer to epitaxial source/drain features) than in center (e.g., directly under the metal gate stack above the ML), thus negatively impacting device performance (e.g., increased SCEs) and increase undesired capacitance. In addition, SiGe in the ML of the present disclosure is negligible (e.g., less than 0.0001% of the total SiGe in the semiconductor layers 204), thus the forming of oxidized Ge during the processes is negligible, which reduces an interface trap effect.

In some embodiments, as depicted in FIG. 12B, in each of the openings 226 between the two adjacent channel layers 206a (or the semiconductor substrate 202, where applicable) (referred to as “top channel layer 206a” and “bottom channel layer 206a”), there are at least one of the remaining dielectric layers 216b (referred as “top remaining dielectric layer 216b” or “bottom remaining dielectric layer 216b”) in direct contact with the top channel layer 206a or the bottom channel layer 206a. The top and/or bottom remaining dielectric layer 216b can have a triangle-like shape in the cross-sectional view as in FIG. 12B. In some embodiments, sidewalls of the top and/or bottom remaining dielectric layer 216b interface with the top and/or bottom channel layer 206a, the adjacent inner spacer 220, and the adjacent gate dielectric layer 232, respectively. In some other embodiments, although not depicted, besides interfacing with these, the top and/or bottom remaining dielectric layer 216b extend to contact with the adjacent epitaxial source/drain feature 223. In such embodiments, the adjacent inner spacer 220 is separated from the top and/or bottom channel layer 206a by the top and/or bottom remaining dielectric layer 216b.

In some embodiments, the top and/or bottom remaining dielectric layer 216b extend between one of the inner spacers 220 (first inner spacer 220) and the gate dielectric layer 232. In some embodiments, the top remaining dielectric layer 216b and the bottom remaining dielectric layer 216b are separated by the first inner spacer 220 and the gate dielectric layer 232 of the metal gate stack. In some other embodiments, the top remaining dielectric layer 216b extends and merges with the bottom remaining dielectric layer 216b. In some embodiments, the top remaining dielectric layer 216b extends to the top channel layer 206a. A top surface of the top remaining dielectric layer 216b and a top surface of the gate dielectric layer 232 can be coplanar, and can be in direct contact with a bottom surface of the top channel layer 206a. Similarly, the bottom remaining dielectric layer 216b extends to the bottom channel layer 206a. A bottom surface of the bottom remaining dielectric layer 216b and a bottom surface of the gate dielectric layers 232 can be coplanar, and can be in direct contact with a top surface of the bottom channel layer 206a.

After forming the gate dielectric layer 232 and the gate electrode 230, a planarization process is performed to remove excess gate materials from the semiconductor structure 200. For example, a CMP process is performed until a top surface of the ILD layer 225 is reached (exposed), such that a top surface of the metal gate stack is substantially planar with the top surface of the ILD layer 225 after the CMP process. Accordingly, the semiconductor structure 200 can include a GAA transistor having a metal gate stack wrapping respective channel layers 206a, such that the metal gate stack is disposed between respective epitaxial source/drain features 223.

Fabrication can proceed to continue fabrication of the semiconductor structure 200. For example, various contacts can be formed to facilitate operation of the GAA transistor. For example, one or more ILD layers, similar to the ILD layer 225, and/or CESL layers can be formed over the semiconductor substrate 202 (in particular, over the ILD layer 225 and the metal gate stack). Contacts can then be formed in the ILD layer 225 and/or ILD layers disposed over the ILD layer 225. For example, a contact is electrically and/or physically coupled with the metal gate stack and another contact is electrically and/or physically coupled to source/drain regions of the GAA transistor (particularly, the epitaxial source/drain features 223). Contacts include a conductive material, such as metal. Metals include aluminum, aluminum alloy (such as aluminum/silicon/copper alloy), copper, copper alloy, titanium, titanium nitride, tantalum, tantalum nitride, tungsten, polysilicon, metal silicide, other suitable metals, or combinations thereof. The metal silicide may include nickel silicide, cobalt silicide, tungsten silicide, tantalum silicide, titanium silicide, platinum silicide, erbium silicide, palladium silicide, or combinations thereof. In some implementations, the ILD layers disposed over the ILD layer 225 and the contacts (for example, extending through the ILD layer 225 and/or the other ILD layers) are a portion of the MLI feature described above.

Other fabrication processes may be applied to the semiconductor structure 200 and may implemented before, during, or after the processes described above, such as various processing steps to form an interconnect structure over the GAA transistors from the frontside of the semiconductor substrate 202 to electrically connects various circuit components. The interconnect structure includes metal lines distributed in multiple metal layers (such as 1^{st} metal layer, 2^{nd} metal layer, 3^{rd} metal layer, and etc. from the bottom up to the top metal layer) to provide horizontal routing and contact features (between the substrate and the first metal layer, and via features (between the metal layers) to provide vertical routing. The semiconductor structure 200 also includes other components, such as other conductive features (such as redistribution layer or RDL), passivation layer(s) to provide sealing effect, and/or bonding structures to provide an interface between the semiconductor structure 200 and a circuit board (such as a printed circuit board) to be formed on the interconnect structure.

Though not intended to be limiting, embodiments of the present disclosure offer benefits for semiconductor processing and semiconductor devices. For example, by removing the non-channel layers including the transition layers before forming the epitaxial source/drain features, SiGe residue becomes negligible before forming the epitaxial source/drain features, thus abnormal doping diffusion and built-in stress (e.g., tensile stress and compressive stress) during following processes are reduced. The early removal of the transition layers also reduces undesired capacitance and device degradation, avoids width loss of channel layers, thus improves performance of the device, reduces short-channel effects (SCEs), and can result in higher current drive and higher logic density.

The fabrication process flow for fabricating the semiconductor structure 200 discussed above may be referred to as a dummy oxide interposer (DOI) process flow, in which the dielectric material 216 (etched to form the dielectric layers 216a of FIG. 7A)—which may also be referred to as a dummy oxide interposer—serves as a sacrificial dielectric layer. As discussed above with reference to FIG. 12A, such a dummy oxide interposer is eventually removed and replaced by the metal gate stack that includes the gate dielectric layer 232 and the gate electrode 230. In order to further optimize device performance and/or yield, additional annealing processes may be performed according to the various aspects of the present disclosure.

For example, referring now to FIG. 13-14, diagrammatic fragmentary cross-sectional side views of the semiconductor structure 200 are illustrated (along the X-Z plane). FIG. 13-14 correspond to the stage of fabrication discussed above with reference to FIGS. 9A-9B. In other words, FIGS. 13-14 illustrate one aspect of the formation of the source/drain features 223. For example, FIG. 13 illustrates a PFET-S/D formation process 300 that is performed to the semiconductor structure 200. The PFET-S/D formation process 300 may include deposition and/or epitaxial growth processes to form the source/drain features 223 discussed above with reference to FIGS. 9A-9B. Thereafter, an annealing process 320 is performed to the semiconductor structure 200, as shown in FIG. 14.

The annealing process 320 helps to improve device performance, for example, by reducing a channel resistance of the semiconductor structure 200. In more detail, the inner spacers 220, as a dielectric material, may interfere with effective dopant diffusion between the channel layers 206a and the source/drain features 223. This results in an increase in channel resistance and/or degradation of electrical properties of the semiconductor structure 200. To address this issue, the annealing process 320 is utilized to further drive the dopants into the channel layers 206a, thereby reducing channel resistance and improving electrical performance of the semiconductor structure 200. For example, the annealing process 320 helps to drive the dopants (e.g., boron dopants) from the source/drain features 223 into the channel layers 206a. As a practical effect, this helps to push a junction between each of the channel layers 206a and the source/drain features 223 toward the channel layer 206a.

To illustrate such a junction push effect in greater detail, referring now to FIG. 15, which is a cross-sectional side view of a magnified portion of the semiconductor structure 200 in the dashed box 340. Specifically, FIG. 15 illustrates one of the channel layers 206a sandwiched vertically (in the Z-direction) between two of the dielectric layers 216a, the source/drain feature 223, and inner spacers 220 disposed between the source/drain feature 223 and the dielectric layers 216a. The channel layer 206a and the source/drain feature 223 form a junction 350, which may also be considered the interface between the channel layer 206a and the source/drain feature 223.

First, it is noted that the DOI process flow of the present disclosure (e.g., discussed above with reference to FIGS. 2-12) inherently helps to improve the profile of the junction 350. In more detail, if the DOI process has not been implemented, then SiGe layers 204 (as dummy or sacrificial semiconductor layers that will be removed later), and not the dielectric layers 216a, would have been implemented to interleave with the channel layer 206a vertically. The SiGe layers 204 may form an intermixing area with the channel layers 206a, where such an intermixing area may have germanium content (due to diffusion from the SiGe layers 204). Unfortunately, germanium may retard the diffusion of boron, which is typically the p-type dopant of the source/drain features 223 of the PFET. As a result, the boron dopants from the source/drain features 223 of the PFET may diffuse into the channel layer 206a at substantially uneven rates, depending on the location of the diffusion.

For example, at or near the center (or a midline) of the channel layer 206a, where germanium content is low or negligible, the diffusion of the boron dopants from the source/drain features 223 into the channel layer 206 may occur faster and/or with greater case. In contrast, at or near the intermixing area between the SiGe layers 204 and the channel layer 206a, the diffusion of the boron dopants from the source/drain features 223 into the channel layer 206 may occur at a substantially slower rate. In this manner, the extent of boron diffusion into the channel layer 206a—which will define the profile of the resulting junction between the channel layer 206a and the source/drain feature 223—may vary as a function of depth within the channel layer 206a: the closer it gets to the SiGe layers 204, the smaller the protrusion of the junction. As a result, the junction formed between the channel layer 206a and the source/drain feature 223 may have a curved shape (e.g., a convex shape from the perspective of the source/drain feature 223), where it protrudes outwardly away from the source/drain feature 223 (and toward the channel layer 206a), particularly at or near its middle.

In comparison, the DOI process flow replaces the SiGe layers 204 with the dielectric layers 216a, which do not contain germanium. This means that an interface 360 between the channel layer 206a and the dielectric layers 216a is also free of germanium, and thus the boron dopant diffusion from the source/drain feature 223 into the channel layer 206a is not retarded by germanium. In other words, the boron dopant from the source/drain feature 223 may diffuse freely and more uniformly into the channel layer 206a, mostly independent of the depth within the channel layer 206a. As a result, the junction 350 between the channel layer 206a and the source/drain feature 223 may lack a concave or a convex shape (which may otherwise exist in devices formed by non-DOI processes) but may have a substantially vertical profile in the cross-sectional side view instead. In other words, a substantial portion (e.g., >90%) of the junction 350 may extend substantially along the Z-direction vertically. In some embodiments, such a substantially vertical profile may be manifested as the junction 350 lacking significant lateral protrusions (e.g., protrusions in the X-direction). For example, to the extent that the junction 350 has small lateral protrusions, an amount of the protrusion—as measured by a distance between an outermost point of the protrusion and an averaged center line of the junction—may be less than N % of a vertical length of the junction 350 in the Z-direction, where N is a specified number. For example, suppose that the vertical length of the junction 350 in the Z-direction is M nanometers, then none of the lateral protrusions may protrude more than M*N % away from the averaged center line of the junction 350. The majority portion of the junction 350 is also substantially perpendicular to the interface 360 (which itself extends in the X-direction) in the cross-sectional side view of FIG. 15. In some embodiments, the channel layer 206a (e.g., to the left of the junction 350) may have a negligibly low concentration of the p-type dopant (e.g., boron), whereas the regions (e.g., region that used to be the channel layer 206 but have now been diffused into by the p-type dopant from the source/drain feature 223) to the right of the junction 350 may have a significantly higher concentration of the p-type dopant. Such a difference in the concentration of the p-type dopant is detectable via certain tools, such as a Secondary Ion Mass Spectrometer (SIMS) tool, which uses a focused beam of ions to remove materials, and which then analyzes the resulting ions in a mass spectrometer.

Again, the relatively uniform profile (e.g., extending substantially vertically in the Z-direction and lacking significant curvatures or lateral protrusions) is one of the inherent results of the semiconductor structure 200 being formed by the DOI process flow, which improves device performance. Nevertheless, the annealing process 320 may further help improve device performance by further activating the boron dopants, which may allow the junction 350 to be pushed closer to the channel layer 206a, as well as to achieve a more uniform (e.g., more vertically straight) profile in the cross-sectional view of FIG. 15.

In some embodiments, the annealing process 320 may include a Rapid Thermal Annealing (RTA) process, a flash annealing process, or a laser annealing process, or combinations thereof. In some embodiments, the annealing process 320 is performed at a temperature greater than about 1050° Celsius (C). In some embodiments, the annealing process 320 is performed at a dwell time less than about 1 second. In some embodiments, the annealing process 320 is performed at a pressure in a range between about 1 torr and about 760 torrs. In some embodiments, the annealing process 320 is performed using a carrier gas such as N2, and/or an inert gas. These process parameters are specifically configured to facilitate the formation and/or the push of the junction 350 toward the channel layer 206a, while also avoiding breaking a desired thermal budget that could otherwise damage other parts of the semiconductor structure 200. It is also understood that the annealing process 320 discussed herein may apply to embodiments using a non-DOI process flow, for example, in embodiments where SiGe layers 204 are used instead of the dielectric layers 216a. In these embodiments, the annealing process 320 may still facilitate the push of the junction 350, though the profile of the junction 350 may exhibit meaningful curvatures due to the boron diffusion being retarded by the presence of germanium in the intermixing areas between the SiGe layers 204 and the channel layer 206a.

It is further understood that the annealing process utilized to achieve further junction push need not be limited to just a single annealing process, nor is it limited to being performed during or immediately after the formation of the PFET source/drain features. In some embodiments, one or more annealing processes may be performed after the formation of the NFET source/drain features.

For example, referring now to referring now to FIG. 16-19, diagrammatic fragmentary three-dimensional perspective views of the semiconductor structure 200 are illustrated (along the X-Z plane). FIG. 16-19 also correspond to the stage of fabrication discussed above with reference to FIGS. 9A-9B. In other words, FIGS. 16-19 also illustrate aspects of the formation of the source/drain features 223. Whereas FIG. 13 illustrates a cross-sectional side view of the formation of the source/drain features 223 for the PFET of the semiconductor structure 200, FIG. 16 illustrates the same PFET S/D formation process 300 in a three-dimensional perspective view. In any case, the source/drain feature 223 of the PFET is formed via the PFET S/D formation process 300 of FIG. 16.

Referring now to FIG. 17, the annealing process 320 discussed above is performed to the semiconductor structure 200 to optimize the junction push for the PFET. It is understood that the PFET S/D formation process 300 may include one or more epitaxial growth processes to grow the source/drain features 223 and/or one or more implantation processes to implant p-type dopants (e.g., boron, or BF₂) into the source/drain features 223. In some embodiments, the annealing process 320 may be performed just after the epitaxial process to grow the source/drain features 223 but before the implantation process(es) to implant the p-type dopants. In other embodiments, the annealing process 320 may be performed after the implantation process(es) to implant the p-type dopants (e.g., boron) into the source/drain features 223 of the PFET. In some embodiments, the annealing process 320 may also include a preheating step having a temperature operating range between about 25 degrees Celsius and about 450 degrees Celsius.

Referring now to FIG. 18, an NFET S/D formation process 400 is performed to form the source/drain features of the NFET. Similar to the PFET S/D formation process 300, the NFET S/D formation process 400 may also include deposition, epitaxial growth, and/or implantation processes to form the source/drain features 223 discussed above with reference to FIGS. 9A-9B, but for NFET devices. In other words, n-type dopants such as phosphorous, phosphorous dimer, or arsenic may be used instead of boron.

Referring now to FIG. 19, an annealing process 420 is performed to the semiconductor structure 200 after the formation of the source/drain features 223 for the NFET. For example, the annealing process 420 may be performed after the implantation process performed to implant n-type dopants into the source/drain features 223 of the NFET. In some embodiments, the annealing process 420 may include a single annealing process. In such a single annealing process, the annealing temperature may be greater than about 1050 degrees Celsius, and the annealing dwell time may be less than 1 second.

In other embodiments, the annealing process 420 may include a plurality of annealing processes. For example, in some embodiments, the annealing process 420 may include a first annealing process that is performed after the n-type dopants are implanted into the source/drain features 223 of the NFET. The type of annealing for the first annealing process may be a rapid thermal annealing process or a flash annealing process, with an operating temperature range between about 600 degrees Celsius and about 1200 degrees Celsius, and an operating range of dwell time of between about 1E−4 (i.e., 0.0001) seconds and about 100 seconds.

The annealing process 420 may further include a second annealing process that is performed after the first annealing process. The type of annealing for the second annealing process may be different from the first annealing process. For example, the second annealing process may include a flash annealing process (in embodiments where the first annealing process is not a flash annealing process), a laser annealing process, a dynamic surface annealing process, or a nanosecond laser annealing process. In embodiments where the laser annealing process is used, the laser annealing process may be performed using a continuous wave laser. In some embodiments, the laser annealing process is performed using a pulsed laser with a repetition rate between about 1 kilo-hertz (kHz) and about 10 mega-hertz (MHz). The laser annealing may be performed in various atmospheres, for example, an oxygen-free atmosphere. In some embodiments, the laser annealing may be performed in a nitrogen atmosphere, a helium atmosphere, or a vacuum atmosphere. These oxygen-free atmospheres may help prevent undesirable oxidation of the various components of the semiconductor structure 200, and accordingly, help to reduce potential defects.

The second annealing process may also have a different operating temperature range or a dwell time than the first annealing process. For example, the second annealing process may have an operating temperature range between about 700 degrees Celsius and about 1300 degrees Celsius, and an operating dwell time range of between about 1E−9 seconds and about 1E−4 seconds (i.e., between about 1 nanosecond and about 0.1 millisecond). As such, it can be seen that the second annealing process has a significantly shorter dwell time and/or a slightly higher temperature than the first annealing process. It is understood that in some embodiments, both the first annealing process and the second annealing process may be conducted under ambient conditions or under an arbitrary gas purge. The annealing process 420 may also have a pressure operating range between about 1 torr and about 760 torrs. In some embodiments, the annealing process 420 may also include a preheating step having a temperature operating range between about 25 degrees Celsius and about 450 degrees Celsius.

In some embodiments, a pre-annealing treatment may also be performed to the source/drain features 223, before the laser annealing, as a part of the annealing process 420. For example, the pre-annealing process may include a rapid thermal annealing process. It is also understood that additional processes may be performed after the second annealing process (e.g., laser annealing). For example, a source/drain contact may be formed over the source/drain feature 223 by depositing a metal layer (e.g., aluminum, copper, or tungsten) on the source/drain feature 223 after the laser annealing.

Regardless of whether the annealing process 420 is a single annealing process or includes multiple annealing processes, it is understood that the annealing process 420 may further facilitate the junction push discussed above, where the junction itself may have a substantially uniform profile. In addition, as an inherent result of the DOI process, the annealing processes performed herein can boost the epi-activation of NFETs without increasing the risk of leakage or accidental damage to the source/drain features 223.

To illustrate, referring now to FIG. 20, which is a magnified cross-sectional side view of an NFET portion of the semiconductor structure 200. FIG. 20 is similar to FIG. 15, except that FIG. 20 corresponds to the NFET portion of the semiconductor structure 200, whereas FIG. 15 corresponds to the PFET portion of the semiconductor structure 200. As shown in FIG. 20, one of the channel layers 206a is also disposed vertically (in the Z-direction) between two of the dielectric layers 216a. A source/drain feature 223 of the NFET is disposed laterally adjacent to the channel layer 206a in the X-direction, and inner spacers 220 are disposed between the source/drain feature 223 and the dielectric layers 216a. The channel layer 206a and the source/drain feature 223 form a junction 450, which may also be referred to as the interface between the channel layer 206a and the source/drain feature 223 of the NFET.

The DOI process flow of the present disclosure (e.g., discussed above with reference to FIGS. 2-12) inherently reduces potential defects associated with metal gate extrusion. In more detail, had the DOI process not been implemented, then SiGe layers 204 (as dummy or sacrificial semiconductor layers that will be removed later) would have been implemented (instead of the dielectric layers 216a) to interleave with the channel layer 206a vertically. The SiGe layers 204 may form an intermixing area with the channel layers 206a, where such an intermixing area may have germanium content (due to diffusion from the SiGe layers 204). Unfortunately, germanium may excessively enhance the diffusion of n-type dopants, such as phosphorous, which is typically the dopant of the source/drain features 223 of the NFET.

As a result, the n-type dopants from the source/drain features 223 of the NFET may diffuse into the channel layer 206a at substantially uneven rates, depending on the location of the diffusion. For example, at or near the center/middle of the channel layer 206a, where germanium content is low or negligible, the diffusion of the n-type dopants from the source/drain features 223 of the NFET into the channel layer 206 may occur at a relatively uniform pace. In contrast, at or near the intermixing area between the SiGe layers 204 and the channel layer 206a, the diffusion of the n-type dopants from the source/drain features 223 of the NFET into the channel layer 206 may occur at a substantially faster rate, as the greater content of the germanium in the intermixing area enhances the diffusion rate and/or amount of the n-type dopants. In this manner, the extent of n-type dopant diffusion into the channel layer 206a—which will define the profile of the resulting junction between the channel layer 206a and the source/drain feature 223—may vary as a function of depth within the channel layer 206a: the closer it gets to the SiGe layers 204, the greater the protrusion of the junction.

As a result, the junction formed between the channel layer 206a and the source/drain feature 223 may have a curved shape, where it protrudes toward from the source/drain feature 223 and away from the channel layer 206a, particularly at or near its middle. In other words, such a junction of the NFET may have an opposite profile than the PFET, where the junction profile of the NFET may have a concave shape (from the perspective of the source/drain feature 223 of the NFET), but the junction profile of the PFET may have a convex shape (from the perspective of the source/drain feature 223 of the PFET). In any case, such a profile of the junction of the NFET may cause potential damage to the source/drain features of the NFET, and/or it may also lead to inadvertent electrical shorting between the source/drain features 223 of the NFET and a metal-containing gate structure that will be formed later to replace the SiGe layers 204.

In comparison, the DOI process flow replaces the SiGe layers 204 with the dielectric layers 216a, which do not contain germanium. This means that an interface 360 between the channel layer 206a and the dielectric layers 216a is also free of germanium, and thus the n-type dopant diffusion from the source/drain feature 223 into the channel layer 206a is not excessively enhanced by germanium. In other words, the n-type dopant from the source/drain feature 223 may diffuse more uniformly into the channel layer 206a, mostly independent of the depth within the channel layer 206a. As a result, the junction 450 between the channel layer 206a and the source/drain feature 223 of the NFET may have a substantially vertical profile in the cross-sectional side view. In other words, similar to the junction 350 of the PFET discussed above, a substantial portion (e.g., >90%) of the junction 450 may also extend substantially along the Z-direction vertically. In some embodiments, such a substantially vertical profile may be manifested as the junction 450 lacking significant lateral protrusions (e.g., protrusions in the X-direction). For example, to the extent that the junction 450 has small lateral protrusions, an amount of the protrusion-as measured by a distance between an outermost point of the protrusion and an averaged center line of the junction-may be less than N % of a vertical length of the junction 450 in the Z-direction, where N is a specified number. The junction 450 is also substantially perpendicular to the interface 360 (which itself extends in the X-direction) in the cross-sectional side view of FIG. 20. In some embodiments, the channel layer 206a (e.g., to the left of the junction 350) may have a negligibly low concentration of the n-type dopant (e.g., phosphorous), whereas the regions (e.g., region that used to be the channel layer 206 but have now been diffused into by the n-type dopant from the source/drain feature 223) to the right of the junction 350 may have a significantly higher concentration of the n-type dopant. Such a difference in the concentration of the p-type dopant is detectable via certain tools, such as the SIMS tool.

Again, the relatively uniform profile (e.g., extending substantially vertically in the Z-direction and lacking significant curvatures or lateral protrusions) is an inherent result of the semiconductor structure 200 being fabricated according to the DOI process flow, which improves device performance by reducing the risks of damage to the source/drain features 223 and/or inadvertently shorting the source/drain features 223 and gate structures to be formed later. Since these risks are reduced, the annealing process 420 discussed above may be performed with less of a concern of causing undesirable damage to the NFET of the semiconductor structure 200. In other words, the present disclosure may offer a larger process window and/or a greater thermal budget for performing various annealing processes (including but not limited to the annealing processes 320 and 420 discussed above), since the annealing processes are less likely to lead to issues for the NFET.

It is understood that annealing processes may also be performed after the removal of the dielectric layers 216a, but before the formation of metal-containing gate structures. For example, referring now to FIG. 21, a diagrammatic fragmentary cross-sectional side view of the semiconductor structure 200 is illustrated. The stage of fabrication shown in FIG. 21 is substantially similar to the stage that was discussed above with reference to FIGS. 11A-11C. That is, the dummy gate structures 210 have been removed to form the trench 228, and the dielectric layers 216a have also been removed to form the openings 226, such that the channels 206a are now suspended. This may be referred to as a sheet formation process. According to the various aspects of the present disclosure, an annealing process 460 may be performed before the metal-containing gate structures are formed in place of the removed dummy gate structures 210. In some embodiments, the annealing process 460 may be an annealing process that is similar to the second annealing process of the annealing process 420 discussed above. For example, the annealing process 460 may be a flash annealing process or a laser annealing process with a relatively high temperature (e.g., between about 700 degrees Celsius and about 1300 degrees Celsius) and a relatively short dwell time (between about 1 nanosecond and about 0.1 millisecond). Such an annealing process 460 may help to improve the quality of the channel layers 206a and/or the quality of the interfacial layers and/or high-k gate dielectric layers of the metal-gate containing structures that will be formed subsequently.

FIG. 22 illustrates a diagrammatic fragmentary cross-sectional side view of the semiconductor structure 200 at a stage of fabrication after the annealing processes 320, 420, and 460 discussed above have been performed, and after the metal-containing gate structures are formed. In other words, the stage of fabrication illustrated in FIG. 22 is substantially similar to the stage of fabrication illustrated in FIGS. 12A-12B. As such, similar components appearing in FIGS. 12-12B and 22 will be labeled the same for reasons of consistency and clarity.

As shown in FIG. 22, the metal-containing gate structure may contain the gate dielectric layer 232 (discussed above with reference to FIGS. 12A-12B) as well as the gate electrode 230. The gate dielectric layer 232 may include a high-k material (e.g., with a dielectric constant greater than about 3.9), and the gate electrode 230 may include a metal material, such as a work function metal and a fill metal. It is also understood that an interfacial layer (e.g., silicon oxide) may be formed between the gate dielectric layer 232 and the channel layer 206, but it is not specifically illustrated herein for reasons of simplicity.

FIG. 22 also illustrates the junction 350/450 discussed above. In other words, when the portion of the semiconductor structure 200 in FIG. 22 corresponds to a PFET, then the junction 350 between the channel layer 206a and the source/drain feature 223 of the PFET is illustrated. Similarly, when the portion of the semiconductor structure 200 in FIG. 22 corresponds to an NFET, then the junction 450 between the channel layer 206a and the source/drain feature 223 of the NFET is illustrated.

Due at least in part to the various annealing processes discussed above, the junction 350/450 may not be vertically co-planar with a side surface of a rest of the source/drain feature 223, but it may be associated with a lateral protrusion (toward the channel layers 206a) of the source/drain feature 223. In some embodiments, the junction 350/450 may be pushed far enough such that it is disposed directly below the gate structure 230/232 (e.g., directly below the bottom surface of the gate dielectric layer 232). In other embodiments, the push of the junction 350/450 may not be as significant, so that the junction 350/450 may be disposed directly below the remaining dielectric layers 216b or directly below the inner spacer 220. Regardless, the pushing of the junction 350 toward the channel 206a is facilitated by the various annealing processes (e.g., the annealing processes 320, 420, and/or 450) discussed above, such that channel resistance may be reduced. Meanwhile, an inherent result of the DOI process flow is that the junction 350/450 may be formed without substantially raising risks of damaging the rest of the semiconductor structure 200 and/or causing undesirable electrical shorting between the gate structure 230/232 and the source/drain feature 223.

It is also noted that the junction 350/450 may inherit the relatively uniform profile of the junction 350/450 discussed above (see FIGS. 15 and 20), which was before the formation of the gate structure 230/232. Such a relatively uniform profile of the junction 350/450 is at least partially attributable to the DOI process flow herein. For example, the junction 350/450 may have a substantially vertical disposition along the Z-direction and may be substantially perpendicular to an interface 360 between the channel layer 206a and the gate structure 230/232. The relatively uniform profile of the junction 350/450 may also be manifested as the fact that a substantial entirety of the junction 350/450 be free of significant lateral protrusions in the X-direction.

FIG. 23 illustrates an example type of memory device in which the semiconductor structure 200 may be implemented. In that regard, FIG. 23 illustrates the circuit schematic of an example Static Random-Access Memory (SRAM) device, for example, as a single-port SRAM cell (e.g., 1-bit SRAM cell) 800. The single-port SRAM cell 800 includes pull-up transistors PU1, PU2; pull-down transistors PD1, PD2; and pass-gate transistors PG1, PG2. As show in the circuit diagram, transistors PU1 and PU2 are p-type transistors, and transistors PG1, PG2, PD1, and PD2 are n-type transistors. According to the various aspects of the present disclosure, the PG1, PG2, PD1, and PD2 transistors are implemented with thinner spacers than the PU1 and PU2 transistors. Since the SRAM cell 800 includes six transistors in the illustrated embodiment, it may also be referred to as a 6T SRAM cell. Regardless, the transistor 710A may be used to implement the PG1, PG2, PD1, PD2, PU1, and/or the PU2 transistors.

The drains of pull-up transistor PU1 and pull-down transistor PD1 are coupled together, and the drains of pull-up transistor PU2 and pull-down transistor PD2 are coupled together. Transistors PU1 and PD1 are cross-coupled with transistors PU2 and PD2 to form a first data latch. The gates of transistors PU2 and PD2 are coupled together and to the drains of transistors PU1 and PD1 to form a first storage node SN1, and the gates of transistors PU1 and PD1 are coupled together and to the drains of transistors PU2 and PD2 to form a complementary first storage node SNB1. Sources of the pull-up transistors PU1 and PU2 are coupled to power voltage Vcc (also referred to as Vdd), and the sources of the pull-down transistors PD1 and PD2 are coupled to a voltage Vss, which may be an electrical ground in some embodiments.

The first storage node SN1 of the first data latch is coupled to bit line BL through pass-gate transistor PG1, and the complementary first storage node SNB1 is coupled to complementary bit line BLB through pass-gate transistor PG2. The first storage node SN1 and the complementary first storage node SNB1 are complementary nodes that are often at opposite logic levels (logic high or logic low). Gates of pass-gate transistors PG1 and PG2 are coupled to a word line WL. SRAM devices such as the SRAM cell 800 may be implemented using “planar” transistor devices, with FinFET devices, and/or with GAA devices.

FIG. 24 illustrates an integrated circuit fabrication system 900 that can be used to fabricate the semiconductor structure 200 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the gate spacers of an SRAM device; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

In summary, the present disclosure uses a unique fabrication process flow to form junctions that have more uniform profiles for GAA devices. In more detail, a DOI process flow is implemented, in which sacrificial dielectric layers (rather than sacrificial SiGe) are implemented to interleave with semiconductor channel layers in a stack. Source/drain features are formed on opposite sides of the semiconductor channel layers, such that a junction is formed between the semiconductor channel layers and the source/drain features. The sacrificial dielectric layers may be replaced later by metal-containing gate structures, which may each circumferentially surround a respective semiconductor channel in the stack. Annealing processes may be performed after the formation of the sacrificial dielectric layers but before the formation of the metal-containing gate structures, so as to facilitate the shifting of the junction toward the semiconductor channel layers, which may be referred to as a junction push.

The present disclosure offers various advantages. However, it is understood that not all advantages are discussed herein, different embodiments may offer different advantages, and that no particular advantage is required for any embodiment. One advantage is improved junction profile as an inherent result of the DOI fabrication process flow. Had the GAA device not been fabricated using the DOI process flow, SiGe layers would have been formed to interleave with the semiconductor channel layers in the stack. The SiGe layers may form an intermixing area with the silicon of the semiconductor channel layers, and the intermixing area may contain germanium. Unfortunately, germanium may retard the diffusion of p-type dopants such as boron, but may promote the excessive diffusion of n-type dopants such as phosphorous or arsenic. As a result, both the PFET and NFET devices may have curved (e.g., concave or convex) junction profiles, which may lead to not only degraded device performance (e.g., high channel resistance), but also potential device defects, such as inadvertent electrical shorting between the metal-gate containing structures and the source/drain features.

Here, by implementing the DOI process flow, sacrificial dielectric layers (rather than SiGe layers) are implemented to interleave with the semiconductor channel layers in the stack. As a result, the interfaces between the sacrificial dielectric layers and the semiconductor channel layers are free of germanium, which means that the diffusion of the p-type dopants from the PFET source/drain features is not unduly retarded, and that the diffusion of the n-type dopants from the NFET source/drain features is not excessively promoted. Consequently, the resulting junctions between the semiconductor channel layers and the source/drain features may have substantially uniform (e.g., substantially vertical) profiles, which may improve device performance (e.g., reduced channel resistance). In addition, the annealing processes performed herein may further facilitate the junction push (e.g., helping to laterally shift the junction toward the semiconductor channel layers), while maintaining a desired thermal budget. Furthermore, compared to non-DOI processes, the processes performed herein are less likely to cause undesirable damage to the GAA components (e.g., to the source/drain features) or cause inadvertent electrical shorting between the metal-containing gate structure and the source/drain features, which may further improved device performance and/or yield. Other advantages may include compatibility with existing fabrication processes and the case and low cost of implementation.

One aspect of the present disclosure pertains to a method. According to the method, a stack of first semiconductor layers and second semiconductor layers is formed. The first semiconductor layers each have a first material composition. The second semiconductor layers each have a second material composition different from the first material composition. The first semiconductor layers interleave with the second semiconductor layers in the stack. The second semiconductor layers are replaced with a plurality of dielectric layers. Source/drain features are formed on opposite sides of the first semiconductor layers, such that junctions are formed between the source/drain features and the first semiconductor layers. One or more annealing processes are performed. At least one of the one or more annealing processes facilitates a push of the junction toward the first semiconductor layers.

Another aspect of the present disclosure pertains to a method. According to the method, a stack of channel layers and sacrificial semiconductor layers that interleave with one another in a vertical direction is formed. The channel layers and the sacrificial semiconductor layers have different material compositions. The sacrificial semiconductor layers are replaced with a plurality of sacrificial dielectric layers. Source/drain components are formed on opposite sides of the channel layers. Each channel forms an interface with the source/drain component. The interfaces are caused to shift laterally toward the channel layers at least in part by performing one or more annealing processes. The sacrificial dielectric layers are removed. A gate structure that is formed to circumferentially wrap around each of the channel layers after the one or more annealing processes have been performed.

Another aspect of the present disclosure pertains to a structure. The structure includes a stack of semiconductor layers disposed over a substrate in a cross-sectional side view. The structure includes a gate structure wrapping around each of the stack of semiconductor layers in the cross-sectional side view. The structure includes a source/drain feature disposed laterally adjacent to the stack of semiconductor layers. The source/drain feature and the semiconductor layers form a plurality of junctions. The junctions protrude laterally away from a rest of the source/drain feature, and the junctions each have a substantially vertical profile in the cross-sectional side view.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack of first semiconductor layers and second semiconductor layers, wherein the first semiconductor layers each have a first material composition, wherein the second semiconductor layers each have a second material composition different from the first material composition, and wherein the first semiconductor layers interleave with the second semiconductor layers in the stack;
replacing the second semiconductor layers with a plurality of dielectric layers;
forming source/drain features on opposite sides of the first semiconductor layers, such that junctions are formed between the source/drain features and the first semiconductor layers; and
performing one or more annealing processes, wherein at least one of the one or more annealing processes facilitates a push of the junctions toward the first semiconductor layers.

2. The method of claim 1, wherein:
the forming of the source/drain features comprises an epitaxial growth process followed by an ion implantation process; and
at least one of the one or more annealing processes is performed after the epitaxial growth process but before the ion implantation process.

3. The method of claim 1, wherein:
the forming of the source/drain features comprises an epitaxial growth process followed by an ion implantation process; and
at least one of the one or more annealing processes is performed after the ion implantation process.

4. The method of claim 1, further comprising:
removing the dielectric layers;
forming metal-containing gate structures in place of the removed dielectric layers; and
at least one of the one or more annealing processes is performed after the dielectric layers are removed but before the metal-containing gate structures are formed.

5. The method of claim 1, wherein at least some of the junctions lack a concave profile or a convex profile in a cross-sectional side view.

6. The method of claim 1, wherein at least one of the annealing processes is performed at a temperature greater than about 1050 degrees Celsius.

7. The method of claim 1, wherein at least one of the annealing processes is performed with a dwell time of less than about 1 second.

8. The method of claim 1, wherein at least one of the annealing processes is performed at a pressure in a range between about 1 torr and about 760 torrs.

9. The method of claim 1, wherein the one or more annealing processes includes a first annealing process and a second annealing process.

10. The method of claim 9, wherein the first annealing process and the second annealing process use different types of annealing techniques.

11. The method of claim 9, wherein the second annealing process has a shorter dwell time than the first annealing process.

12. The method of claim 11, wherein the dwell time for the second annealing process is in a range between about 1 nanosecond and about 0.1 millisecond.

13. The method of claim 9, wherein the second annealing process, but not the first annealing process, includes a laser annealing process.

14. A method, comprising:
forming a stack of channel layers and sacrificial semiconductor layers that interleave with one another in a vertical direction, wherein the channel layers and the sacrificial semiconductor layers have different material compositions;
replacing the sacrificial semiconductor layers with a plurality of sacrificial dielectric layers;
forming source/drain components on opposite sides of the channel layers, wherein each channel forms an interface with the source/drain component;
causing the interfaces to shift laterally toward the channel layers at least in part by performing one or more annealing processes;
removing the sacrificial dielectric layers; and
forming a gate structure that circumferentially wraps around each of the channel layers after the one or more annealing processes have been performed.

15. The method of claim 14, wherein:
the forming of the source/drain components includes an epitaxial growth process followed by an ion implantation process;
the one or more annealing processes includes a first annealing process that is performed after the epitaxial growth process and a second annealing process that is performed after the ion implantation process; and
the second annealing process is performed with a shorter dwell time than the first annealing process.

16. The method of claim 14, wherein at least one of the one or more annealing processes is performed after the sacrificial dielectric layers are removed but before the gate structure is formed.

17. A structure, comprising:
a stack of semiconductor layers disposed over a substrate in a cross-sectional side view;
a gate structure wrapping around each of the stack of semiconductor layers in the cross-sectional side view; and
a source/drain feature disposed laterally adjacent to the stack of semiconductor layers, wherein the source/drain feature and the semiconductor layers form a plurality of junctions, wherein the junctions protrude laterally away from a rest of the source/drain feature, and wherein the junctions each have a substantially vertical profile in the cross-sectional side view.

18. The structure of claim 17, wherein the junctions are disposed directly below the gate structure.

19. The structure of claim 17, further comprising a plurality of dielectric inner spacers disposed between the source/drain feature and the gate structure, wherein the junctions are disposed directly below respective ones of the dielectric inner spacers.

20. The structure of claim 19, further comprising a dielectric material disposed between portions of the dielectric inner spacers and the gate structure, wherein the dielectric material and the dielectric inner spacers have different material compositions.
